(19) United States
(12) Patent Application Publication
(10) Pub. No.: US 2026/0040724 A1
(43) Pub. Date: Feb. 5, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Sin-Yi Jiang, Hsinchu City (TW); Po-Chun Liu, Hsinchu City (TW); Yi-Shin Chu, Hsinchu City (TW); Hsiang-Lin Chen, Hsinchu County (TW); Yin-Kai Liao, Taipei City (TW); Sung-Wen Huang Chen, Nantou County (TW); Hsing-Chih Lin, Tainan City (TW)

(21) Appl. No.: 18/976,403

(22) Filed: Dec. 11, 2024

Related U.S. Application Data
(60) Provisional application No. 63/678,676, filed on Aug. 2, 2024.

(51) Int. Cl. H10F 77/30; H10F 30/225; H10F 39/10; H10F 71/00; H10F 77/00

(52) U.S. Cl. CPC H10F 77/306; H10F 30/225; H10F 39/103; H10F 71/129; H10F 77/933

(57) ABSTRACT

Various embodiments of the present disclosure are directed towards an integrated chip (IC). The IC includes a substrate comprising a first material. A semiconductor layer is on the substrate and comprises a second material different from the first material. A buffer layer is arranged between the semiconductor layer and the substrate. The buffer layer comprises the first material and the second material.

### REFERENCE TO RELATED APPLICATION

This application claims the benefit of U.S. Provisional Application No. 63/678,676, filed on Aug. 2, 2024, the contents of which are hereby incorporated by reference in their entirety.

### BACKGROUND

Image sensors are solid-state devices that are configured to convert incoming light into an electrical signal. The electrical signal is then provided to a processor that can convert the electrical signal to data that can be stored and/or viewed by a user. Integrated chips (ICs) with image sensors are used in a wide range of modern-day electronic devices, such as cell phones, cameras, medical devices, etc.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates a cross-sectional view of some embodiments of an integrated chip (IC) comprising a buffer layer disposed between a substrate and a semiconductor layer of a photodetector.

FIGS. 2A-2B illustrate various views of some other embodiments of an IC comprising a buffer layer disposed between a substrate and a semiconductor layer of a photodetector.

FIGS. 3A-3B illustrate various views of some other embodiments of the IC of FIGS. 2A-2B.

FIGS. 4A-4B illustrate various views of some other embodiments of an IC comprising a buffer layer disposed between a substrate and a semiconductor layer of a photodetector.

FIGS. 5A-5B illustrate various views of some other embodiments of the IC of FIGS. 4A-4B.

FIGS. 6A-6B illustrate cross-sectional views of some other embodiments of the IC of FIG. 1.

FIGS. 7A-7B illustrate various views of some other embodiments of the IC of FIGS. 2A-2B, where the buffer layer comprises a plurality of buffer films.

FIG. 7C illustrate a cross-sectional view of some other embodiments of the IC of FIG. 6A, where the buffer layer comprises a plurality of buffer films.

FIGS. 7D-7F illustrate various cross-sectional views of some other embodiments of an IC comprising a buffer layer disposed between a substrate and a semiconductor layer of a photodetector.

FIGS. 8A-8B through 21A-21B illustrate a series of various views of some embodiments of a method for forming an IC comprising a buffer layer disposed between a substrate and a semiconductor layer of a photodetector.

FIG. 22 illustrates a flow diagram of some embodiments of a method of forming an IC comprising a buffer layer disposed between a substrate and a semiconductor layer of a photodetector.

FIGS. 23-29 illustrate a series of cross-sectional views of some other embodiments of a method for forming an IC comprising a buffer layer disposed between a substrate and a semiconductor layer of a photodetector.

FIGS. 30-42 illustrate a series of cross-sectional views of some other embodiments of a method for forming an IC comprising a buffer layer disposed between a substrate and a semiconductor layer of a photodetector.

FIG. 43 illustrates a flow diagram of some embodiments of a method of forming an IC comprising a buffer layer disposed between a substrate and semiconductor layer of a photodetector.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Image sensor integrated chips (ICs) may comprise photodetectors configured to detect infrared (IR) radiation. This facilitates the image sensor ICs being employed in time-of-flight (ToF) depth sensing or other suitable applications. However, image sensor ICs typically comprise silicon based photodetectors. Silicon has a large bandgap, where the absorption coefficient of silicon decreases as a wavelength of radiation increases. As a result, silicon-based photodetectors may have low quantum efficiency (QE) for IR radiation. To increase QE for IR radiation, silicon based photodetectors may be replaced by germanium based photodetectors. Germanium has a small bandgap compared to silicon and therefore has higher absorption in the IR spectrum compared to silicon. Thus, germanium based photodetectors have high QE for IR radiation.

A method for forming a germanium based photodetector may include etching a silicon substrate to form a trench extending into the silicon substrate, forming a germanium layer in the trench and contacting the silicon substrate, and forming a photodetector in the germanium layer. However, it has been appreciated that different lattice constants between the silicon substrate and the germanium layer may lead to defects (e.g., dislocation defects) along an interface between the silicon substrate and the germanium layer. The defects can reduce a crystalline quality of the germanium layer and cause dark current leakage within the photodetector, thereby reducing a signal-to-noise ratio (SNR), QE, etc. of the photodetector. As a result, an ability to accurately detect IR radiation may be reduced.

Some embodiments of the present disclosure are directed towards an integrated chip (IC) having a buffer layer disposed between a substrate and a semiconductor layer of a photodetector. The substrate comprises a first material (e.g., silicon) and the semiconductor layer comprises a second material (e.g., germanium) different from the first material. The buffer layer is arranged between the substrate and the semiconductor layer and comprises the first material and the second material. By comprising the first and second materials, the buffer layer is able to mitigate issues due to the different lattice constants of the semiconductor layer and the substrate. This reduces defects between the semiconductor layer and the substrate, thereby increasing a crystalline quality of the semiconductor layer and decreasing dark current in the photodetector. As a result, the SNR, QE, and overall performance of the photodetector is increased.

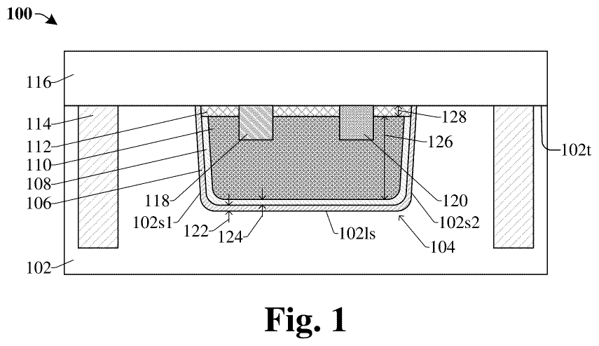

FIG. 1 illustrates a cross-sectional view 100 of some embodiments of an integrated chip (IC) comprising a buffer layer 108 disposed between a substrate 102 and a semiconductor layer 110 of a photodetector 104.

The IC comprises the substrate 102 that has one or more surfaces defining a trench that extends into a top surface 102t of the substrate 102. For example, the substrate 102 comprises opposing sidewalls 102s1, 102s2 and a lower surface 1021s that defines the trench. The photodetector 104 comprises the semiconductor layer 110 disposed within the recess and one or more doped regions 118, 120. The substrate 102 comprises a first material and the semiconductor layer 110 comprises a second material different from the first material. In some embodiments, the first material is or comprises silicon, crystalline silicon, and/or some other semiconductor material(s). In some embodiments, a bulk of the substrate 102 comprises a first doping type (e.g., p-type). In various embodiments, the second material is or comprises germanium, silicon germanium (SiGe) having a high concentration of germanium, silicon carbide (SiC), or the like. In further embodiments, the semiconductor layer 110 consists essentially of germanium, silicon germanium, or silicon carbide. In some embodiments, a bulk of the semiconductor layer 110 is undoped. For example, the semiconductor layer 110 is or comprises an intrinsic form of the second material (e.g., comprises intrinsic germanium). In further embodiments, the bulk of the semiconductor layer 110 comprises the first doping type (e.g., p-type) with a doping concentration of approximately 5.69e15 to 9.4e14 atoms/cm³ or less, or some other suitable value.

An interlayer 106 extends along the opposing sidewalls 102s1, 102s2 and the lower surface 1021s of the substrate 102 that defines the trench. The interlayer 106 is arranged between the substrate 102 and the semiconductor layer 110. The interlayer 106 is or comprises a same material as the substrate 102 that is different from the second material of the semiconductor layer 110. The interlayer 106 may, for example, be or comprise silicon, epitaxial silicon, or some other semiconductor material(s). In various embodiments, the interlayer 106 is undoped. In some embodiments, a top surface of the interlayer 106 is aligned with the top surface 102t of the substrate 102.

A buffer layer 108 is arranged along opposing sidewalls and a lower surface of the semiconductor layer 110. The buffer layer 108 is arranged between the interlayer 106 and the semiconductor layer 110. In some embodiments, the buffer layer 108 directly contacts the opposing sidewalls and the lower surface of the semiconductor layer 110. Further, the buffer layer 108 comprises the first material (e.g., silicon) and the second material (e.g., germanium). In various embodiments, the buffer layer 108 is undoped. In various embodiments, the buffer layer 108 is a single continuous layer that continuously extends from inner surfaces of the interlayer 106 to outer surfaces of the semiconductor layer 110. In such embodiments, a first concentration of the first material (e.g., silicon) in the buffer layer 108 may continuously decrease from the interlayer 106 to the semiconductor layer 110 and a second concentration of the second material (e.g., germanium) in the buffer layer 108 may continuously increase from the interlayer 106 to the semiconductor layer 110. In further embodiments, the buffer layer 108 may comprise a plurality of individual buffer films (not shown) that have varying concentrations of the first and second materials relative to one another. In various embodiments, a top surface of the buffer layer 108 is aligned with a top surface of the semiconductor layer 110. Further, top surfaces of the buffer layer 108 and the semiconductor layer 110 may be recessed below the top surface 102t of the substrate 102 by a non-zero distance.

In some embodiments, when the first material of the substrate 102 is silicon and the second material of the semiconductor layer 110 is germanium, the buffer layer 108 comprises silicon germanium (e.g., SiₓGe₁₋ₓ, where x is in a range of 1 to 0). In such embodiments, the buffer layer 108 may comprise a relatively thin (e.g., having a thickness of 2 to 3 nanometers (nm) or less) region or film along the interlayer 106 that comprises silicon, where a remaining portion of the buffer layer 108 comprises SiₓGe₁₋ₓ, where x is in a range of 0.995 to 0. In further embodiments, when the semiconductor layer 110 comprises silicon germanium and the substrate 102 comprises silicon, the buffer layer 108 comprises silicon germanium. In such embodiments, a concentration of germanium in the semiconductor layer 110 may be greater than a maximum concentration of germanium in the buffer layer 108. In yet further embodiments, when the semiconductor layer 110 comprises silicon carbide and the substrate comprises silicon, the buffer layer comprises silicon carbide (e.g., SiₓC₁₋ₓ, where x is in a range of 1 to 0).

A passivation layer 112 overlies the buffer layer 108 and the semiconductor layer 110. In some embodiments, the passivation layer 112 continuously extends along the top surface of the buffer layer 108 and the top surface of the semiconductor layer 110 to inner opposing sidewalls of the interlayer 106. The passivation layer 112 is or comprises a same material as the substrate 102 that is different from the second material of the semiconductor layer. The passivation layer 112 may, for example, be or comprise silicon, epitaxial silicon, or some other suitable material. In various embodiments, a bulk of the passivation layer 112 is undoped. The passivation layer 112 may be referred to as a capping layer or a protective layer. An isolation structure 114 is arranged on opposing sides of the semiconductor layer 110 and extends from the top surface 102t of the substrate 102 to a point below the interlayer 106. The isolation structure 114 is configured to increase optical and/or electrical isolation between the photodetector 104 and adjacent photodetectors (not shown). Further, a dielectric structure 116 overlies the substrate 102.

In various embodiments, the photodetector 104 further comprises a first doped region 118 and a second doped region 120. The first doped region 118 comprises the first doping type (e.g., p-type) and the second doped region 120 comprises a second doping type (e.g., n-type) opposite the first doping type. In various embodiments, the first and second doped regions 118, 120 extend from the passivation layer 112 to the semiconductor layer 110. In various embodiments, the first doping type is p-type and the second doping type is n-type, or vice versa. In some embodiments, the first and second doped regions 118, 120 each have a doping concentration within a range of approximately 1e16 to 1e17 atoms/cm³, or some other suitable value.

During operation of the IC, incident electromagnetic radiation that strikes the semiconductor layer 110 can cause an electron-hole pair to be generated in the semiconductor layer 110. Bias voltages may be applied to the first and second doped regions 118, 120 to form an electric field within the semiconductor layer 110. The electric field can move an electron released from the generation of the electron-hole pair to the second doped region 120, thereby generating a photocurrent. The generated photocurrent may be detected and/or read by readout circuitry (not shown). Thus, the photodetector 104 is configured to convert the incident electromagnetic radiation into electrical signals. The semiconductor layer 110 comprising the second material (e.g., germanium) with a relatively small bandgap (e.g., less than that of silicon) facilitates the photodetector 104 having increased absorption of IR radiation (e.g., radiation having a wavelength that is in a range of approximately 700 to 3,000 nm). As a result, the photodetector 104 comprising the semiconductor layer 110 with the second material (e.g., germanium) increases a QE of the photodetector 104 for IR radiation. In some embodiments, the photodetector 104 may be configured as a PIN photodiode, a PN photodiode, an avalanche photodiode, a depth sensor, or the like.

In various embodiments, a first lattice constant of the substrate 102 is different from a second lattice constant of the semiconductor layer 110. The buffer layer 108 comprises a compound of the first and second materials, such the buffer layer 108 has a lattice constant that is in a range between the first lattice constant and the second lattice constant. The lattice constant of the buffer layer 108 is a better match to the second lattice constant of the semiconductor layer 110 than the first lattice constant of the substrate 102. As a result, the buffer layer 108 is configured to reduce defects between the substrate 102 and the semiconductor layer 110 and provide a good structural foundation that facilitates forming or growing the semiconductor layer 110 with a high crystalline quality. Thus, by the buffer layer 108 comprising the compound of the first and second materials and being disposed along horizontally and vertically extending interfaces between the substrate 102 and the semiconductor layer 110, leakage current (e.g., dark current) in the photodetector 104 is reduced and a performance of the photodetector 104 is increased.

In various embodiments, during fabrication of the IC, an etch process (e.g., a dry etch) is performed on the substrate 102 to form the opposing sidewalls 102s1, 102s2 and the lower surface 1021s of the substrate 102 that define the recess. Ion bombardment from the etch process may result in crystalline defects (e.g., dangling bonds) along the opposing sidewalls 102s1, 102s2 and/or the lower surface 1021s of the substrate 102. In some embodiments, the interlayer 106 is formed or grown by an epitaxial process along the opposing sidewalls 102s1, 102s2 and the lower surface 1021s of the substrate 102. The interlayer 106 is configured to passivate the crystalline defects from the etch process and provide for a better structural foundation for subsequent layers (e.g., the buffer layer 108, semiconductor layer 110, and/or the passivation layer 112) formed on the interlayer 106. As a result, the buffer layer 108, the semiconductor layer 110, and/or the passivation layer 112 each have a higher crystalline quality and leakage current is further decreased, thereby further increasing a performance of the photodetector 104.

A thickness 122 of the interlayer 106 is, for example, equal to or greater than 40 nm, within a range of approximately 40 nm to 50 nm, or some other suitable value. In some embodiments, the thickness 122 being equal to or greater than 40 nm facilitates the interlayer 106 growing on the substrate 102 with a high crystalline quality that matches a crystalline structure of the substrate 102. As a result, the interlayer 106 may reduce issues due to crystalline defects along surfaces of the substrate 102 defining the recess, thereby providing a better structural foundation for forming the buffer layer 108 and the semiconductor layer 110. In some embodiments, the thickness 122 being equal to or less than 50 nm increases space in the recess for the semiconductor layer 110, thereby increasing a QE of the photodetector 104.

A thickness 124 of the buffer layer 108 is greater than 10 nm, within a range of approximately 10 nm to 100 nm, within a range of approximately 30 nm to 100 nm, or some other suitable value. In some embodiments, the thickness 124 being equal to or greater than 10 nm facilitates the buffer layer 108 growing with a high crystalline quality and being sufficiently thick to provide a good structural foundation for forming the semiconductor layer 110 with reduced defects between the substrate 102 and the semiconductor layer 110. In some embodiments, the thickness 124 being equal to or less than 100 nm facilitates scaling down the size of the photodetector 104 and increasing the QE of the photodetector 104 by increasing space in the recess for the semiconductor layer 110. In various embodiments, the thickness 124 of the buffer layer 108 is less than the thickness 122 of the interlayer 106.

A thickness 126 of the semiconductor layer 110 is, for example, equal to or greater than 1 micrometer (um), within a range of approximately 1 um to 1.4 um, or some other suitable value. In some embodiments, the thickness 126 being equal to or greater than 1 um increases a sensing area for the photodetector 104 for target electromagnetic radiation (e.g., IR radiation), thereby increasing a QE of the photodetector 104. In some embodiments, the thickness 126 being equal to or less than 1.4 um decreases damage to the substrate 102 during the etch process utilized to form the recess (e.g., by decreasing a power and/or duration of the etch process utilized to form the recess) and/or facilitates scaling down the size of the photodetector 104.

In some embodiments, a ratio of the thickness 124 of the buffer layer 108 to the thickness of the thickness 126 of the semiconductor layer 110 is within a range of 0.01 to 0.10. In various embodiments, the ratio of the thickness 124 to the thickness 126 being greater than or equal to 0.01 facilitates the buffer layer 108 being sufficiently thick to provide a good structural foundation to form the semiconductor layer 110 and reduce defects between the substrate 102 and the semiconductor layer 110. In further embodiments, the ratio of the thickness 124 to the thickness 126 being equal to or less than 0.10 facilitates the buffer layer 108 better matching the second lattice constant of the semiconductor layer 110 while increasing the QE of the photodetector 104. For example, the buffer layer 108 may have a lower absorption of IR radiation than the semiconductor layer 110, such that the ratio of the thickness 124 to the thickness 126 being equal to or less than 0.10 facilitates the semiconductor layer 110 being sufficiently thick enough to increase absorption of IR radiation.

In various embodiments, the passivation layer 112 directly contacts the top surfaces of the semiconductor layer 110 and the buffer layer 108. In further embodiments, a top surface of the passivation layer 112 is aligned with the top surface 102t of the substrate 102. The passivation layer 112 is configured to mitigate damage to the buffer layer 108 and/or the semiconductor layer 110 during fabrication of the IC. For example, the passivation layer 112 may mitigate damage to the buffer layer 108 and the semiconductor layer 110 during one or more etching processes (e.g., wet etch(es)) performed on the substrate 102 after forming the semiconductor layer 110. This increases a performance and reliability of the photodetector 104. A thickness 128 of the passivation layer 112 is, for example, greater than 40 nm, within a range of approximately 40 nm to 50 nm, or some other suitable value. In some embodiments, the thickness 128 being equal to or greater than 40 nm facilitates the passivation layer 112 being sufficiently thick to protect the semiconductor layer 110. In some embodiments, the thickness 128 being equal to or less than 50 nm increases a sensing area of the photodetector 104, thereby increasing the QE of the photodetector 104. In some embodiments, the thickness 128 of the passivation layer 112 is greater than the thickness 124 of the buffer layer 108. In some embodiments, the thickness 128 of the passivation layer 112 is equal to the thickness 122 of the interlayer 106.

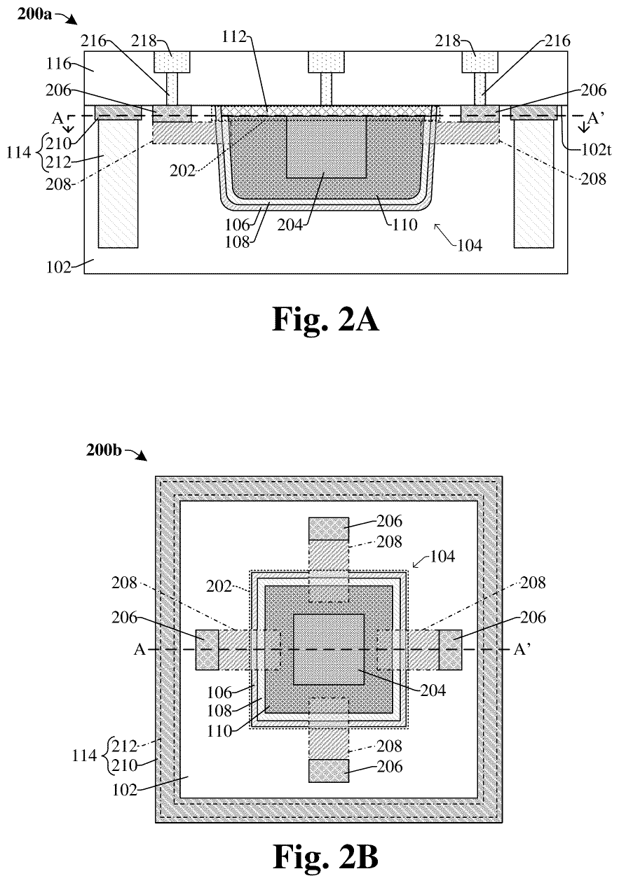

FIG. 2A illustrates a cross-sectional view 200a of an IC according to some other embodiments of the IC of FIG. 1.

In some embodiments, the photodetector 104 comprises the semiconductor layer 110, a plurality of first contact regions 206, a second contact region 202, a plurality of outer lateral wells 208, and a middle well region 204. The bulk of the substrate 102 comprises the first doping type (e.g., p-type). The plurality of first contact regions 206 are disposed in the substrate 102 on opposing sides of the semiconductor layer 110. The plurality of first contact regions 206 comprise the second doping type (e.g., n-type). In various embodiments, each of the first contact regions 206 are spaced between the semiconductor layer 110 and a corresponding side of the isolation structure 114. The first contact regions 206 are laterally offset from the interlayer 106. Further, the first contact regions 206 continuously extend from the top surface 102t of the substrate 102 to a point below the top surface 102t.

Each outer lateral well in the plurality of outer lateral wells 208 underlies a corresponding contact region in the plurality of first contact regions 206 and continuously laterally extends from under the corresponding contact region to the semiconductor layer 110. In various embodiments, the outer lateral wells 208 extend laterally from the substrate 102, through a corresponding upper region of the interlayer 106 and the buffer layer 108 to the semiconductor layer 110. The plurality of outer lateral wells 208 comprise the second doping type (e.g., n-type). It will be appreciated that at least a portion of the outer lateral wells 208 extending into the interlayer 106, the buffer layer 108, and the semiconductor layer 110 are represented in phantom for case of illustration.

The second contact region 202 is arranged in the passivation layer 112 and the semiconductor layer 110. The second contact region 202 comprises the first doping type (e.g., p-type). It will be appreciated that the second contact region 202 is represented in phantom for case of illustration. The second contact region 202 continuously extends from a top surface of the passivation layer 112 into an upper region of the semiconductor layer 110. The second contact region 202 extends from the passivation layer 112 to the substrate 102 and upper edge regions of the interlayer 106 and the buffer layer 108. In some embodiments, a width of the second contact region 202 is greater than a width of the passivation layer 112 and a width of the semiconductor layer 110.

The middle well region 204 is arranged in the semiconductor layer 110 below the passivation layer 112. The middle well region 204 comprises the first doping type (e.g., p-type). In some embodiments, the middle well region 204 continuously extends from a top surface of the semiconductor layer 110 to a point below the top surface of the semiconductor layer 110. In some embodiments, the bulk of the semiconductor layer 110 offset from the middle well region 204 and the second contact region 202 comprises the first doping type (e.g., p-type) having a doping concentration less than a doping concentration of the middle well region 204. In yet further embodiments, the bulk of the semiconductor layer 110 is undoped. The middle well region 204 is spaced between the outer lateral wells 208. A bottom of the middle well region 204 is disposed below bottoms of the outer lateral wells 208.

The dielectric structure 116 is arranged over the top surface 102t of the substrate 102. In some embodiments, the dielectric structure 116 comprises one or more dielectric layers that may each comprise silicon dioxide, silicon carbide, silicon nitride, some other dielectric material, or any combination of the foregoing. A plurality of conductive contacts 216 are arranged in the dielectric structure 116. The conductive contacts 216 overlie and are electrically coupled to a corresponding one of the first and second contact regions 206, 202. A plurality of conductive wires 218 are arranged in the dielectric structure 116 and overlie the conductive contacts 216. The conductive contacts and wires 216, 218 may, for example, be or comprise copper, aluminum, tungsten, ruthenium, titanium nitride, tantalum nitride, some other conductive material, or any combination of the foregoing.

The isolation structure 114 is arranged in the substrate 102 and continuously wraps around an outer perimeter of the semiconductor layer 110. In some embodiments, the isolation structure 114 comprises an upper isolation doped region 210 and a lower isolation doped region 212 underlying the upper isolation doped region 210. The upper isolation doped region 210 and the lower isolation doped region 212 are doped regions of the substrate 102 that each comprise the first doping type (e.g., p-type). In various embodiments, a doping concentration of the upper isolation doped region 210 is greater than a doping concentration of the lower isolation doped region 212. Further, the doping concentration of the lower isolation doped region 212 is greater than a doping concentration of the bulk of the substrate 102. The isolation structure 114 is configured to increase electrical isolation between the photodetector 104 and other photodetectors (not shown) disposed in the substrate 102.

During operation of the IC, incident electromagnetic radiation that strikes the semiconductor layer 110 can cause an electron-hole pair to be generated in the semiconductor layer 110. Bias voltages may be applied to the first and second contact regions 206, 202 to generate an electric field in the semiconductor layer 110, where the electric field can move a released electron (e.g., released from generation of the electron-hole pair) to the outer lateral wells 208, thereby generating a photocurrent that may be detected and/our read by readout circuitry (not shown). Thus, in some embodiments, the released electron may travel laterally from a middle region of the semiconductor layer 110 (e.g., from the middle well region 204) to the outer lateral wells 208. By virtue of the buffer layer 108 comprising the compound of the first material (e.g., silicon) and the second material (e.g., germanium) defects (e.g., dislocation defects) at interfaces between the semiconductor layer 110 and the substrate 102 may be reduced. In some embodiments, because the outer lateral wells 208 extend from the substrate 102, through sidewalls of the interlayer 106, buffer layer 108, and semiconductor layer 110, the reduction of defects mitigates leakage current in the photodetector 104. For example, an increased number of defects at the interfaces between the semiconductor layer 110 and the substrate 102 may cause a high generation of free charge carries (e.g., through thermal generation) in the outer lateral wells 208 that can result in high dark leakage current. In such embodiments, the free charge carries may be difficult to distinguish from electrons released in the semiconductor layer 110 from incident electromagnetic radiation. Thus, the buffer layer 108 comprising the compound of the first and second materials and being spaced between the substrate 102 and the semiconductor layer 110 decreases leakage current and increases a performance (e.g., increases a QE, SNR, etc.) of the photodetector 104. In some embodiments, the photodetector 104 is configured as a PN photodiode, a PIN photodiode, or the like.

In some embodiments, the middle well region 204, the bulk of the substrate 102, the second contact region 202, the upper isolation doped region 210, and the lower isolation doped region 212 comprise first dopants (e.g., boron, aluminum, gallium, or the like) having the first doping type (e.g., p-type). In various embodiments, a doping concentration of the second contact region 202 is greater than a doping concentration of the middle well region 204. The doping concentration of the second contact region 202 may, for example, be within a range of approximately 1e17 to 1e18 atoms/cm³, or some other suitable value. The doping concentration of the middle well region 204 may, for example, be within a range of approximately 1e16 to 1e17 atoms/cm³, or some other suitable value. In some embodiments, a doping concentration of the upper isolation doped region 210 is greater than a doping concentration of the lower isolation doped region 212. The doping concentration of the upper isolation doped region 210 may, for example, be within a range of approximately 1e18 to 1e20 atoms/cm³, or some other suitable value. The doping concentration of the lower isolation doped region 212 may, for example, be within a range of approximately 1e16 to 1e18 atoms/cm³, or some other suitable value.

In some embodiments, the first contact regions 206 and the outer lateral wells 208 comprise second dopants (e.g., arsenic, antimony, phosphorus, or the like) having the second doping type (e.g., n-type). In some embodiments, a doping concentration of the first contact regions 206 is greater than a doping concentration of the outer lateral wells 208. The doping concentration of the first contact regions 206 may, for example, be within a range of approximately 1e18 to 1e19 atoms/cm³, or some other suitable value. The doping concentration of the outer lateral wells 208 may, for example, be within a range of approximately 1e16 to 1e17 atoms/cm³, or some other suitable value. In various embodiments, the doping concentration of the first contact regions 206 is greater than the doping concentration of the second contact region 202.

FIG. 2B illustrates a top view 200b of some embodiments of the IC of FIG. 2A. The cross-sectional view 200a of FIG. 2A may, for example, be taken along line A-A′ in FIG. 2B. The top view 200b of FIG. 2B may, for example, be taken along line A-A′ in FIG. 2A.

As illustrated in FIG. 2B, the buffer layer 108 continuously laterally extends around an outer perimeter of the semiconductor layer 110. The interlayer 106 continuously laterally extends around an outer perimeter of the buffer layer 108. The isolation structure 114 continuously laterally extends around the semiconductor layer 110 and is laterally offset from the interlayer 106. In some embodiments, the middle well region 204 is aligned with a middle of the semiconductor layer 110.

The plurality of outer lateral wells 208 comprise an individual outer lateral well arranged at each side of the semiconductor layer 110. For example, in some embodiments, the semiconductor layer 110 has a rectangular shape when viewed in top view and the plurality of outer lateral wells 208 comprises an individual outer lateral well at each of the four sides of the semiconductor layer 110. It will be appreciated that the semiconductor layer 110 may have other shapes when viewed in top view. In various embodiments, the plurality of first contact regions 206 comprises an individual contact region over a corresponding outer lateral well in the plurality of outer lateral wells 208. In further embodiments, the outer lateral wells 208 are each laterally offset from a corresponding side of the middle well region 204 by a non-zero distance that may, for example, be greater than a thickness of the buffer layer 108.

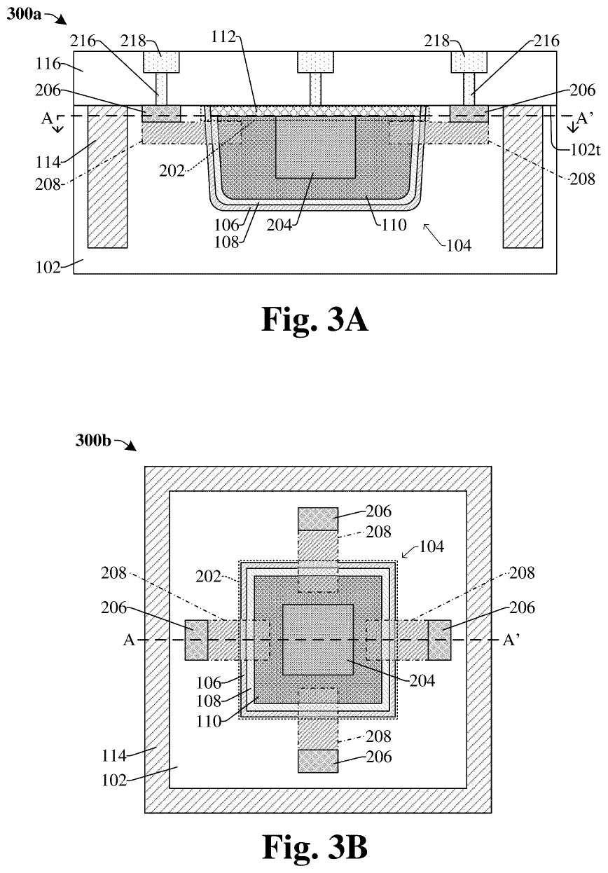

FIGS. 3A-3B illustrate a cross-sectional view 300a and a top view 300b of an IC according to some other embodiments of the IC of FIGS. 2A-2B. The cross-sectional view 300a of FIG. 3A may, for example, be taken along line A-A′ in FIG. 3B. The top view 300b of FIG. 3B may, for example, be taken along line A-A′ in FIG. 3A.

In some embodiments, the isolation structure 114 comprises a dielectric material disposed in a trench that extends into the top surface 102t of the substrate 102. The dielectric material of the isolation structure 114 may, for example, be or comprise silicon dioxide, silicon oxynitride, silicon nitride, silicon carbide, some other dielectric material, or any combination of the foregoing.

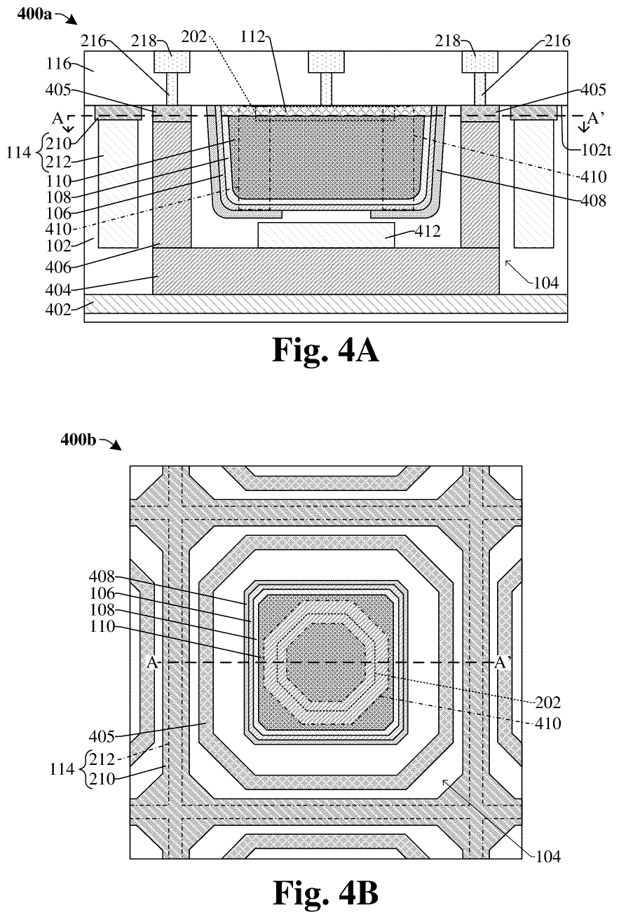

FIGS. 4A and 4B illustrate a cross-sectional view 400a and a top view 400b corresponding to some other embodiments of FIG. 1, where the photodetector 104 is configured as an avalanche photodiode (APD), a single-photon avalanche diode (SPAD), or the like. The cross-sectional view 400a of FIG. 4A may, for example, be taken along line A-A′ in FIG. 4B. The top view 400b of FIG. 4B may, for example, be taken along line A-A′ in FIG. 4A.

As illustrated in FIG. 4A, in some embodiments, the photodetector 104 comprises the semiconductor layer 110, a first avalanche well 404, a second avalanche well 412, a vertical connection well 406, a first contact region 405, a second contact region 202, and a guard ring region 410. A bottom well 402 is disposed in the substrate 102 below the first avalanche well 404. The first avalanche well 404 underlies the semiconductor layer 110. The bottom well 402 comprises the first doping type (e.g., p-type) and the first avalanche well 404 comprises the second doping type (e.g., n-type). The first contact region 405 is disposed in the substrate 102 on opposing sides of the semiconductor layer 110 and comprises the second doping type (e.g., n-type). In some embodiments, the first contact region 405 is ring-shaped and laterally extends around the semiconductor layer 110 (e.g., as shown in FIG. 4B). The vertical connection well 406 is disposed in the substrate 102 and continuously vertically extends from the first contact region 405 to the first avalanche well 404. The vertical connection well 406 comprises the second doping type (e.g., n-type). In some embodiments, when viewed from top view the vertical connection well 406 is ring-shaped and laterally extends around the semiconductor layer 110.

The second avalanche well 412 is disposed in the substrate 102 between the semiconductor layer 110 and the first avalanche well 404. The second avalanche well 412 comprises the first doping type (e.g., p-type). The second contact region 202 is arranged in the passivation layer 112 and the semiconductor layer 110. The second contact region 202 comprises the first doping type (e.g., p-type). It will be appreciated that the second contact region 202 is represented in phantom for ease of illustration. The second contact region 202 continuously extends from a top surface of the passivation layer 112 into an upper region of the semiconductor layer 110. In some embodiments, a width of the second contact region 202 is less than a width of the semiconductor layer 110. Further, the guard ring region 410 is arranged in the semiconductor layer 110. It will be appreciated that the guard ring region 410 is represented in phantom for case of illustration. In some embodiments, the guard ring region 410 continuously extends from the top surface of the passivation layer 112 through the semiconductor layer 110 and the buffer layer 108 to a bottom surface of the interlayer 106. In various embodiments, when viewed from top view, the guard ring region 410 is ring-shaped. The guard ring region 410 comprises the first doping type (e.g., p-type).

A doped surface region 408 is disposed in the substrate 102 along sidewalls of the interlayer 106 and a lower surface of the interlayer 106. The doped surface region 408 comprises the first doping type (e.g., p-type). In some embodiments, a thickness of the doped surface region 408 along the interlayer 106 is approximately 500 angstroms, within a range of approximately 450 to 550 angstroms, or some other suitable value. In various embodiments, the doped surface region 408 comprises a higher doping concentration than that of the bulk of the substrate 102 and may passivate crystalline defects along surfaces of the substrate 102 that define the recess. In such embodiments, the crystalline defects may, for example, be from an etch process (e.g., a dry etch) used to form the recess in the substrate 102. By passivating the crystalline defects, the doped surface region 408 further reduces dark current in the photodetector 104. In some embodiments, the isolation structure 114 comprises the upper isolation doped region 210 and the lower isolation doped region 212 underlying the upper isolation doped region 210. The isolation structure 114 may be configured as illustrated and/or described in FIGS. 2A-2B.

In some embodiments, during operation of the IC, the first contact region 405 is configured as a cathode of the photodetector 104 and the second contact region 202 is configured as an anode of the photodetector 104. Incident electromagnetic radiation that strikes the semiconductor layer 110 can cause an electron hole pair to be generated in the semiconductor layer 110. The photodetector 104 may be reverse biased by way of the plurality of conductive contacts and wires 216, 218. For example, the photodetector 104 may be reversed biased above its breakdown voltage. As a result, a high electric field is generated across the photodetector 104 such that released charge carriers (e.g., electrons released from the generated electron hole pair) move towards and are accelerated at an avalanche region between the first and second avalanche wells 404, 412. This triggers an avalanche current that increases an electrical signal generated by the incident electromagnetic radiation and increases detection of the incident electromagnetic radiation. By virtue of the buffer layer 108 comprising the compound of the first material (e.g., silicon) and the second material (e.g., germanium) defects (e.g., dislocation defects) at interfaces between the semiconductor layer 110 and the substrate 102 may be reduced. In some embodiments, because the second avalanche well 412 is arranged between the semiconductor layer 110 and the first avalanche well 404, the reduction of defects mitigates leakage current in the photodetector 104. Thus, the buffer layer 108 comprising the compound of the first and second materials and being spaced between the substrate 102 and the semiconductor layer 110 decreases leakage current and increases a performance (e.g., increases a QE, SNR, etc.) of the photodetector 104.

In various embodiments, the doped surface region 408 is laterally offset and continuously wraps around a middle region of the semiconductor layer 110. This, in part, may facilitate directing charge carries from the semiconductor layer 110 to the first and second avalanche wells 404, 412. In further embodiments, when viewed in top view (e.g., as seen in FIG. 4B) the guard ring region 410 is ring-shaped and assists in redistributing the electric field in the photodetector 104 such that it is more uniform. Further, the guard ring region 410 may isolate the middle region of the semiconductor layer 110 from outer regions of the semiconductor layer 110. As a result, a premature breakdown of the photodetector 104 may be mitigated and leakage current is further reduced, thereby increasing a stability and performance of the photodetector 104.

In some embodiments, the bottom well 402, the doped surface region 408, the bulk of the substrate 102, the second contact region 202, the guard ring region 410, and the second avalanche well 412 comprise first dopants (e.g., boron, aluminum, gallium, or the like) having the first doping type (e.g., p-type). In various embodiments, a doping concentration of the second contact region 202 is greater than a doping concentration of the guard ring region 410 and/or is greater than a doping concentration of the second avalanche well 412. The doping concentration of the second contact region 202 may, for example, be within a range of approximately 1e17 to 1e18 atoms/cm³, or some other suitable value. The doping concentration of the guard ring region 410 may, for example, be within a range of approximately 1e16 to 1e17 atoms/cm³, or some other suitable value. The doping concentration of the doped surface region 408 may, for example, be within a range of approximately 1e18 to 2e19 atoms/cm³, or some other suitable value. The doping concentration of the second avalanche well 412 may, for example, be approximately 3.5e17 atoms/cm³, be within a range of approximately 1e17 to 1e18 atoms/cm³, or some other suitable value.

In some embodiments, the first contact region 405, the vertical connection well 406, and the first avalanche well 404 comprise second dopants (e.g., arsenic, antimony, phosphorus, or the like) having the second doping type (e.g., n-type). In some embodiments, a doping concentration of the first contact region 405 is greater than a doping concentration of the vertical connection well 406 and/or is greater than a doping concentration of the first avalanche well 404. The doping concentration of the first contact region 405 may, for example, be within a range of approximately 1e18 to 1e19 atoms/cm³, or some other suitable value. The doping concentration of the first avalanche well 404 may, for example, be within a range of approximately 1e17 to 1e18 atoms/cm³, or some other suitable value. The doping concentration of the vertical connection well 406 may, for example, be within a range of approximately 4e17 to 8e17 atoms/cm³, or some other suitable value.

As illustrated in FIG. 4B, in some embodiments, the doped surface region 408 continuously laterally extends around the outer perimeter of the interlayer 106. The first contact region 405 continuously laterally extends around and is laterally spaced from the interlayer 106. Further, the guard ring region 410 is ring-shaped and wraps around the second contact region 202.

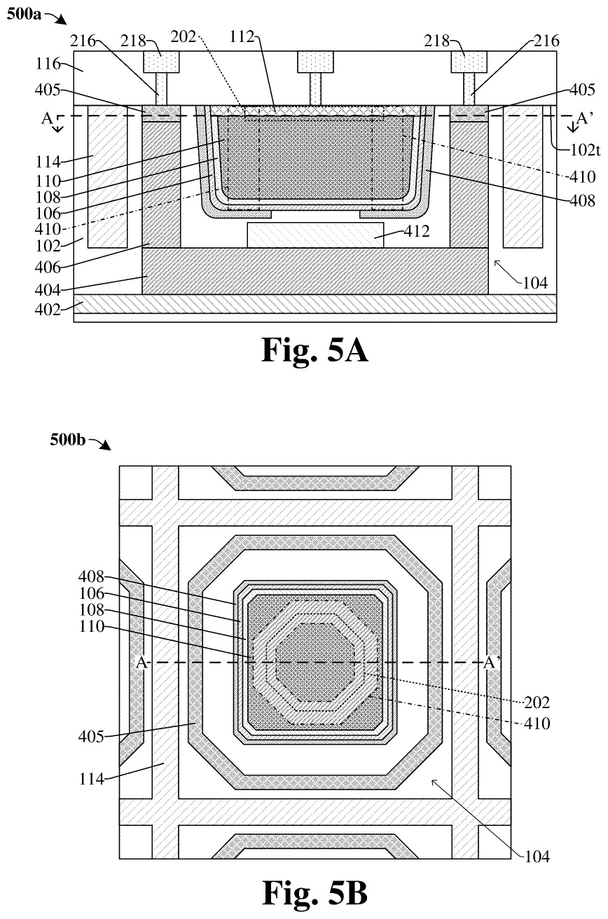

FIGS. 5A-5B illustrate a cross-sectional view 500a and a top view 500b corresponding to some other embodiments of the IC of FIGS. 4A-4B. The cross-sectional view 500a of FIG. 5A may, for example, be taken along line A-A′ in FIG. 5B. the top view 500b of FIG. 5B may, for example, be taken along line A-A′ in FIG. 5A.

In some embodiments, the isolation structure 114 comprises a dielectric material disposed in a trench that extends into the top surface 102t of the substrate 102. The dielectric material of the isolation structure 114 may, for example, be or comprise silicon dioxide, silicon oxynitride, silicon nitride, silicon carbide, some other dielectric material, or any combination of the foregoing. In various embodiments, a bottom surface of the isolation structure 114 is aligned with a bottom of the vertical connection well 406 and/or a bottom of the second avalanche well 412.

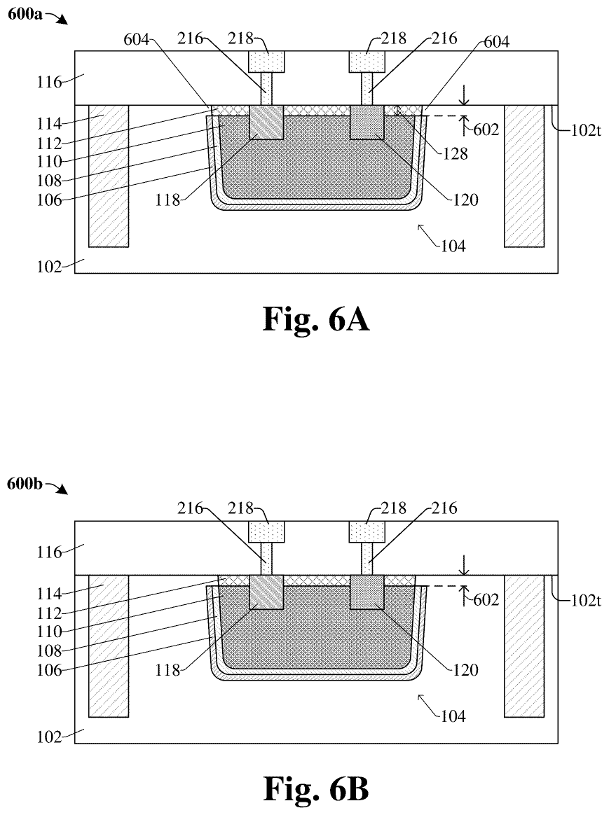

FIG. 6A illustrates a cross-sectional view 600a of an IC according to some other embodiments of the IC of FIG. 1.

In some embodiments, a top surface of the interlayer 106 is vertically offset from the top surface 102t of the substrate 102 by a vertical distance 602. The vertical distance 602 may, for example be within a range of approximately 40 to 50 nm or some other suitable value. In various embodiments, the vertical distance 602 is equal to the thickness 128 of the passivation layer 112. In various embodiments, upper segments 604 of the substrate 102 continuously extend from the top surface of the interlayer 106 to outer sidewalls of the passivation layer 112. In some embodiment, this further increases an ability for the passivation layer 112 to properly grow and/or be formed over the semiconductor layer 110 and mitigate damage to the buffer layer 108 and/or the semiconductor layer 110 during fabrication of the IC. In further embodiments, the top surface of the interlayer 106 is vertically aligned with a top surface of the semiconductor layer 110 and a top surface of the buffer layer 108. In some embodiments, the outer sidewalls of the passivation layer 112 are aligned with outer sidewalls of the buffer layer 108. Further, a plurality of conductive contacts 216 and a plurality of conductive wires 218 are disposed in the dielectric structure 116 and are coupled to the first and second doped regions 118, 120.

FIG. 6B illustrates a cross-sectional view 600b corresponding to some other embodiments of the IC of FIG. 6A, where the outer sidewalls of the passivation layer 112 are aligned with the outer sidewalls of the semiconductor layer 110.

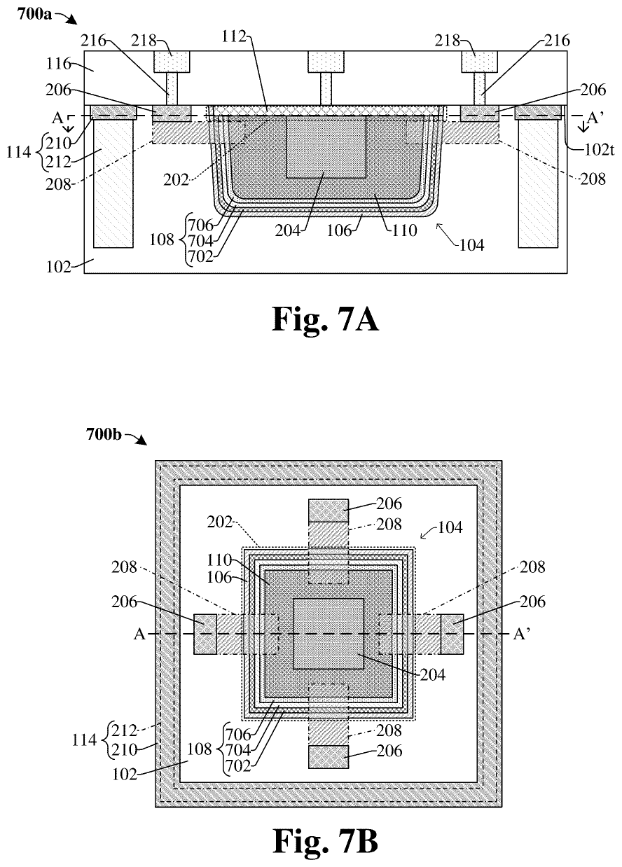

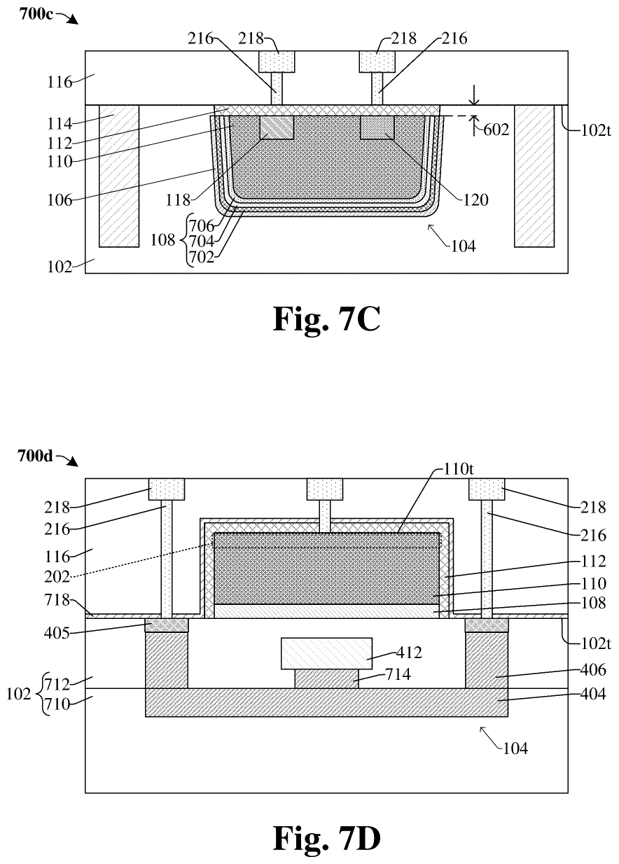

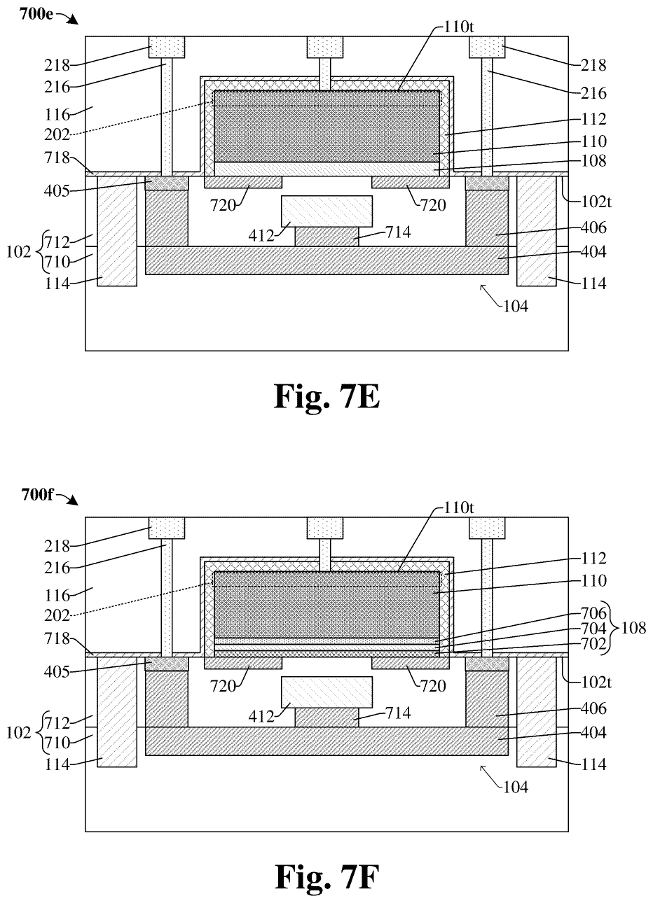

FIG. 7A-7B illustrates a cross-sectional view 700a and a top view 700b of an IC according to some other embodiments of the IC of FIGS. 2A-2B, where the buffer layer 108 comprises a plurality of buffer films 702-706.

With reference to FIG. 7A, in some embodiments, the buffer layer 108 comprises a first buffer film 702, a second buffer film 704, and a third buffer film 706. The first buffer film 702 is arranged between the interlayer 106 and the second buffer film 704. The second buffer film 704 is arranged between the first buffer film 702 and the third buffer film 706. The third buffer film 706 is arranged between the second buffer film 704 and the semiconductor layer 110. In various embodiments, top surfaces of the first, second, and third buffer films 702, 704, 706 are coplanar with one another and/or the top surface of the semiconductor layer 110.

The substrate 102 comprises the first material and the semiconductor layer 110 comprises the second material different from the first material. The plurality of buffer films 702-706 comprise a compound of the first material (e.g., silicon) and the second material (e.g., germanium) with varying concentrations of the first and second materials. In some embodiments, a concentration of the first material discretely decreases across the buffer layer 108 from the first buffer film 702 to the third buffer film 706 and a concentration of the second material discretely increases across the buffer layer 108 from the first buffer film 702 to the third buffer film 706. For example, a concentration of the first material in the first buffer film 702 is greater than a concentration of the first material in the second buffer film 704 and the concentration of the first material in the second buffer film 704 is greater than a concentration of the first material in the third buffer film 706. Further, a concentration of the second material in the first buffer film 702 is less than a concentration of the second material in the second buffer film 704 and the concentration of the second material in the second buffer film 704 is less than a concentration of the second material in the third buffer film 706. This change in concentrations of the first and second materials across the plurality of buffer films 702-706 facilitates the buffer layer 108 being grown with a high crystalline quality and facilitates better matching the second lattice constant of the semiconductor layer 110, thereby decreasing leakage current in the photodetector 104. In some embodiments, the first buffer film 702 comprises Si_{0.75}Ge_{0.25}, the second buffer film 704 comprises Si_{0.50}Ge_{0.50}, and the third buffer film 706 comprises Si_{0.25}Ge_{0.75}, however it will be appreciated that the plurality of buffer films 702-706 comprising other concentrations of the first and second materials is within the scope of the disclosure.

In various embodiments, a lattice constant of the first buffer film 702 is greater than the first lattice constant of the substrate 102, a lattice constant of the second buffer film 704 is greater than the lattice constant of the first buffer film 702, a lattice constant of the third buffer film 706 is greater than the lattice constant of the second buffer film 704. Thus, the lattice constant of the buffer layer 108 discretely increases at least two times from the first buffer film 702 to the third buffer film 706. As a result, strain across the buffer layer 108 is decreased, thereby increasing a structural integrity of the buffer layer 108. In various embodiments, a lattice constant of the interlayer 106 is equal to the first lattice constant of the substrate 102. In some embodiments, the second lattice constant of the semiconductor layer 110 is greater than the lattice constant of the third buffer film 706.

In various embodiments, thicknesses of the first, second, and third buffer films 702-706 are respectively within a range of 10 nm to 30 nm, or some other suitable value. In various embodiments, the thickness of the first buffer film 702 is less than the thickness of the second buffer film 704, and the thickness of the second buffer film 704 is less than the thickness of the third buffer film 706. This, in part, facilitates the buffer layer 108 further decreasing defects between the semiconductor layer 110 and the substrate 102, thereby further decreasing leakage current in the photodetector 104. In various embodiments, the thickness of the second buffer film 704 is at least 10% greater than the thickness of the first buffer film 702, and the thickness of the third buffer film 706 is at least 10% greater than the thickness of the second buffer film 704. Thus, thicknesses of the plurality of buffer films 702-706 discretely increases from the first buffer film 702 to the third buffer film 706. It will be appreciated that while FIG. 7A illustrates some other embodiments of the IC of FIG. 2A, the buffer layer 108 of any one of FIGS. 3A-3B, 4A-4B, and/or 5A-5B may be configured as illustrated and/or described in FIG. 7A.

With reference to FIG. 7B, the interlayer 106 continuously wraps around an outer perimeter of the first buffer film 702. The first buffer film 702 continuously wraps around an outer perimeter of the second buffer film 704. The second buffer film 704 continuously wraps around an outer perimeter of the third buffer film 706.

FIG. 7C illustrates a cross-sectional view 700c of some other embodiments of the IC of FIG. 6A, where the buffer layer 108 comprises the plurality of buffer films 702-706 as illustrated and/or described in FIG. 7A.

FIG. 7D illustrates a cross-sectional view 700d of some other embodiments of the IC of FIGS. 4A and 4B, where the semiconductor layer 110 is arranged above the top surface 102t of the substrate 102.

In some embodiments, the substrate 102 comprises a base substrate 710 and an upper substrate layer 712 on the base substrate 710. The base substrate 710 may, for example, be or comprise silicon, monocrystalline silicon, some other semiconductor material, or any combination of the foregoing. The upper substrate layer 712 may, for example, be or comprise silicon, epitaxial silicon, some other semiconductor material, or any combination of the foregoing. In some embodiments, a thickness of the upper substrate layer 712 is less than a thickness of the base substrate 710. In various embodiments, the base substrate 710 and the upper substrate layer 712 both comprise the first material (e.g., silicon). The base substrate 710 and/or the upper substrate layer 712 may have the first doping type (e.g., p-type).

In various embodiments, the photodetector 104 comprises the semiconductor layer 110, a first avalanche well 404, a second avalanche well 412, an avalanche well extension region 714, a vertical connection well 406, a first contact region 405, and a second contact region 202. The semiconductor layer 110 overlies the substrate 102. The first avalanche well 404 is arranged in the base substrate 710. In some embodiments, the first avalanche well 404 continuously extends along a top surface of the base substrate 710. The avalanche well extension region 714 is arranged in the upper substrate layer 712 along a top of the first avalanche well 404. The avalanche well extension region 714 is aligned with a middle region of the first avalanche well 404. The second avalanche well 412 is arranged in the upper substrate layer 712 over the avalanche well extension region 714. The vertical connection well 406 is arranged in the upper substrate layer 712 and extends from the first contact region 405 to the first avalanche well 404. In various embodiments, the vertical connection well 406 and the first contact region 405 are each ring shaped when viewed in top view (e.g., as illustrated and/or described in FIG. 4B). The avalanche well extension region 714 has the second doping type (e.g., n-type). In various embodiments, a width of the avalanche well extension region 714 is less than a width of the second avalanche well 412 and the avalanche well extension region 714 is configured to enhance and/or better confine released charged carriers at the avalanche region between the first and second avalanche wells 404, 412.

The semiconductor layer 110 is arranged above the top surface 102t of the substrate 102. The top surface 102t of the substrate 102 may be defined by a top surface of the upper substrate layer 712. In various embodiments, a bottom surface of the semiconductor layer 110 is vertically offset from the top surface 102t of the substrate 102 by a non-zero distance. The buffer layer 108 is arranged between the top surface 102t of the substrate 102 and the semiconductor layer 110. In some embodiments, outer sidewalls of the buffer layer 108 are aligned with outer sidewalls of the semiconductor layer 110. In various embodiments, the passivation layer 112 directly contacts a top surface 110t and the outer sidewalls of the semiconductor layer 110. Further, the passivation layer 112 directly contacts the outer sidewalls of the buffer layer 108. In some embodiments, a bottom surface of the passivation layer 112 is aligned with a bottom surface of the buffer layer 108. The passivation layer 112 continuously wraps around and contacts an outer perimeter of the semiconductor layer 110. By virtue of the passivation layer 112 being disposed on the top surface 110t and the outer sidewalls of the semiconductor layer 110 and the outer sidewalls of the buffer layer 108, damage to the buffer layer 108 and/or the semiconductor layer 110 may be mitigated. In various embodiments, the second contact region 202 is arranged in the semiconductor layer 110 and may extend into the passivation layer 112.

An etch stop layer 718 overlies the substrate 102 and extends along opposing sidewalls and a top surface of the passivation layer 112. The etch stop layer 718 may, for example, be or comprise silicon nitride, silicon carbide, some other dielectric material, or any combination of the foregoing. The dielectric structure 116 overlies and laterally encloses the semiconductor layer 110. In some embodiments, a bottom surface of a conductive contact 216 arranged over the first contact region 405 is disposed below the bottom surface of the semiconductor layer 110 and/or is aligned with a bottom surface of the buffer layer 108.

The upper substrate layer 712 comprises the first material (e.g., silicon) and the semiconductor layer 110 comprises the second material (e.g., germanium). By virtue of the buffer layer 108 comprising the compound of the first material and the second material, the lattice constant of the buffer layer 108 is a good match to the lattice constant of the semiconductor layer 110. Thus, the buffer layer 108 provides a good structural foundation for forming or growing the semiconductor layer 110 with high crystalline quality. Further, disposing the semiconductor layer 110 over the top surface 102t of the substrate 102 may, for example, mitigate defects between outer sidewalls of the semiconductor layer 110 and the substrate 102. In addition, the semiconductor layer 110 overlying the top surface 102t mitigates leakage current at outer regions of the semiconductor layer 110 and enhances optical and/or electrical isolation between the photodetector 104 and other photodetectors (not shown) over and/or in the substrate 102, thereby increasing a performance of the photodetector 104.

FIG. 7E illustrates a cross-sectional view 700e of some other embodiments of the IC of FIG. 7D, where an isolation structure 114 is arranged in the substrate 102 on opposing sides of the first avalanche well 404 and an upper doped surface region 720 is in the upper substrate layer 712. In various embodiments, the isolation structure 114 continuously extends from the top surface 102t to the base substrate 710. The upper doped surface region 720 has the first doping type (e.g., p-type) and has a doping concentration greater than a bulk of the substrate 102. Further, the upper doped surface region 720 is laterally offset and continuously wraps around a region laterally aligned with a middle region of the semiconductor layer 110. This may facilitate directing charge carriers from the semiconductor layer 110 to the first and second avalanche wells 404, 412.

FIG. 7F illustrates a cross-sectional view 700f of some other embodiments of the IC of FIG. 7D, where the buffer layer 108 comprises the plurality of buffer films 702-706 as illustrated and/or described in FIG. 7A.

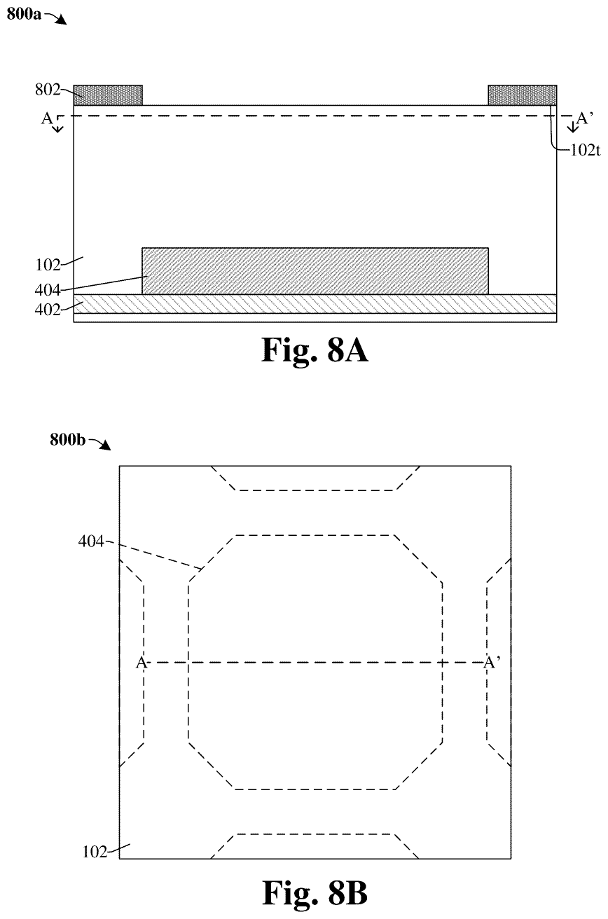

FIGS. 8A-8B through 21A-21B illustrate a series of various views of some embodiments of a method for forming an integrated chip (IC) comprising a buffer layer disposed between a substrate and a semiconductor layer of a photodetector. Figures with a suffix of “A” illustrate a cross-sectional view of the IC during various formation processes. Figures with a suffix of “B” illustrate a top view taken along the line A-A′ of Figures with a suffix of “A.”

Although the various views shown in FIGS. 8A-8B through 21A-21B are described with reference to a method of forming the IC, it will be appreciated that the structures shown in FIGS. 8A-8B through 21A-21B are not limited to the method of formation but rather may stand alone separate of the method. Furthermore, although FIGS. 8A-8B through 21A-21B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 800a and top view 800b of FIGS. 8A-8B, a substrate 102 is provided and a bottom well 402 and a first avalanche well 404 are formed in the substrate 102. The substrate 102 comprises a first material and may be doped with first dopants having a first doping type (e.g., p-type). In some embodiments, the first material is or comprises silicon, crystalline silicon, or some other semiconductor material(s). In some embodiments, forming the bottom well 402 includes performing a first doping process that implants first dopants (e.g., boron, aluminum, gallium, or the like) having the first doping type (e.g., p-type) into the substrate 102. The first doping process may, for example, include a blanket implantation process. In some embodiments, forming the first avalanche well 404 includes: forming an implant mask 802 over the substrate 102; performing a second doping process to implant second dopants (e.g., arsenic, antimony, phosphorus, or the like) having the second doping type (e.g., n-type) into the substrate 102 with the implant mask 802 in place; and removing the implant mask 802.

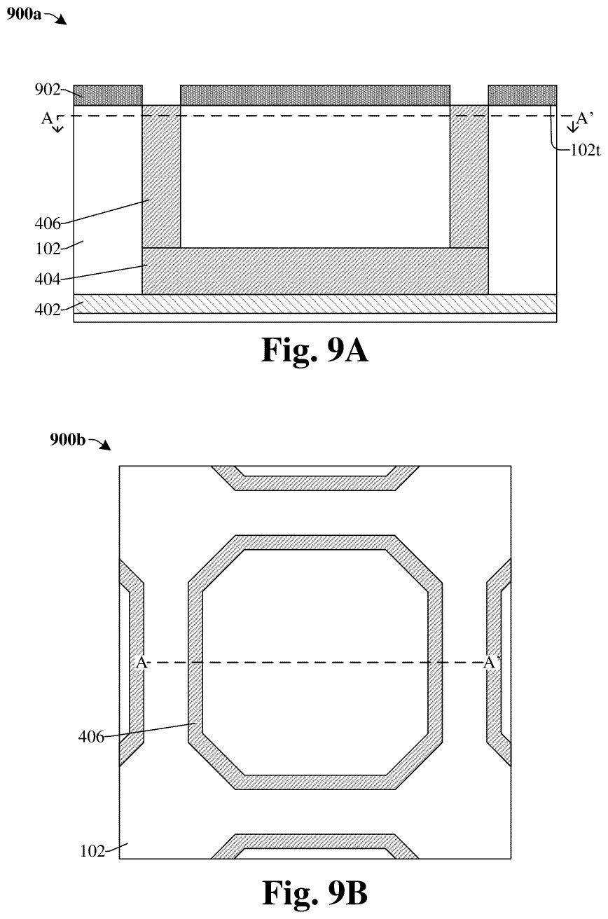

As shown in cross-sectional view 900a and top view 900b of FIGS. 9A-9B, a vertical connection well 406 is formed in the substrate 102. In some embodiments, forming the vertical connection well 406 includes: forming an implant mask 902 over the substrate 102; performing a doping process to implant second dopants (e.g., arsenic, antimony, phosphorus, or the like) having the second doping type (e.g., n-type) into the substrate 102 with the implant mask 902 in place; and removing the implant mask 902.

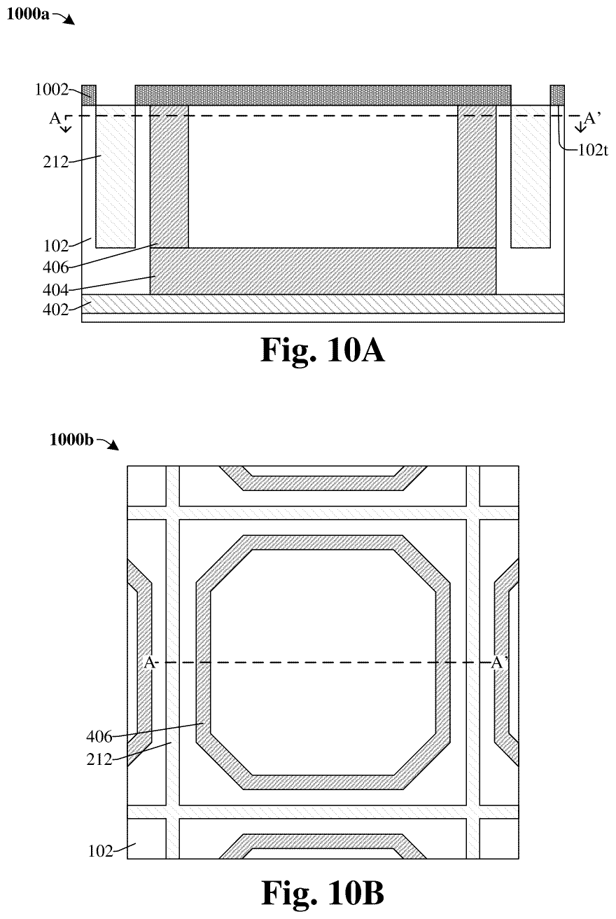

As shown in cross-sectional view 1000a and top view 1000b of FIGS. 10A-10B, a lower isolation doped region 212 is formed in the substrate 102. The lower isolation doped region 212 continuously extends around the vertical connection well 406. In some embodiments, forming the lower isolation doped region 212 includes: forming an implant mask 1002 over the substrate 102; performing a doping process to implant first dopants (e.g., boron, aluminum, gallium, or the like) having the first doping type (e.g., p-type) into the substrate 102 with the implant mask 1002 in place; and removing the implant mask 1002.

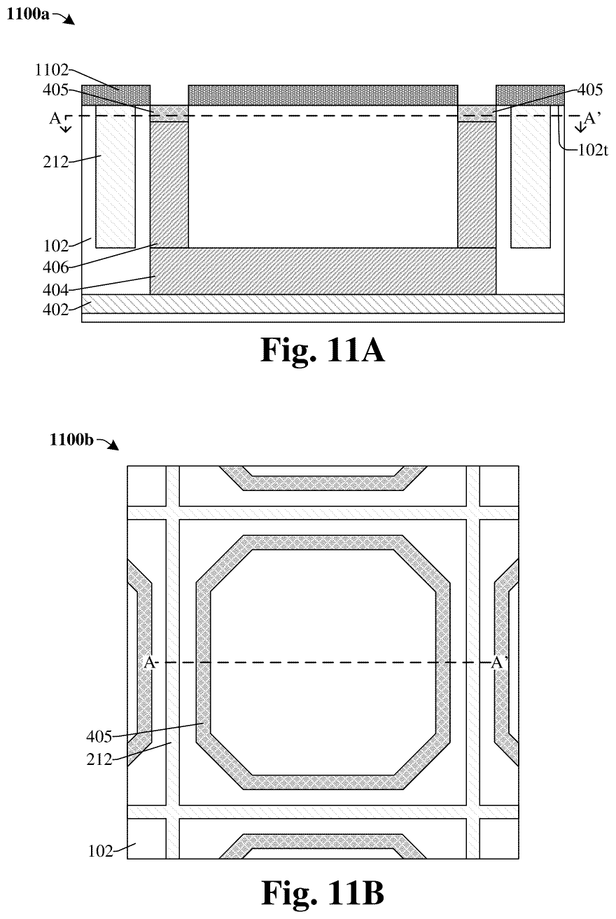

As shown in cross-sectional view 1100a and top view 1100b of FIGS. 11A-11B, a first contact region 405 is formed in the substrate 102 over the vertical connection well 406. In some embodiments, forming the first contact region 405 includes: forming an implant mask 1102 over the substrate 102; performing a doping process to implant second dopants (e.g., arsenic, antimony, phosphorus, or the like) having the second doping type (e.g., n-type) into the substrate 102 with the implant mask 1102 in place; and removing the implant mask 1102.

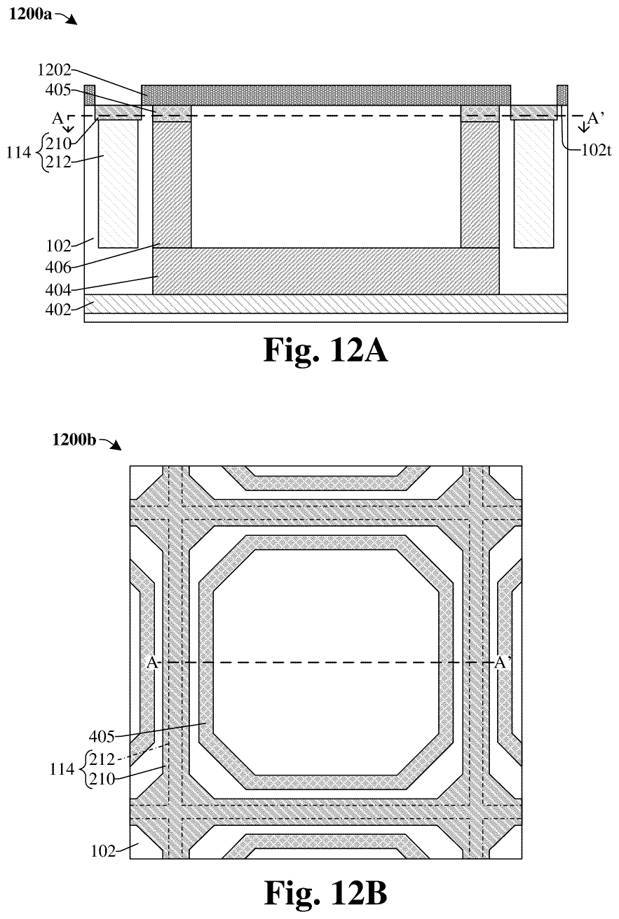

As shown in cross-sectional view 1200a and top view 1200b of FIGS. 12A-12B, an upper isolation doped region 210 is formed in the substrate 102 over the lower isolation doped region 212, thereby forming or defining an isolation structure 114. In some embodiments, forming the upper isolation doped region 210 includes: forming an implant mask 1202 over the substrate 102; performing a doping process to implant first dopants (e.g., boron, aluminum, gallium, or the like) having the first doping type (e.g., p-type) into the substrate 102 with the implant mask 1202 in place; and removing the implant mask 1202.

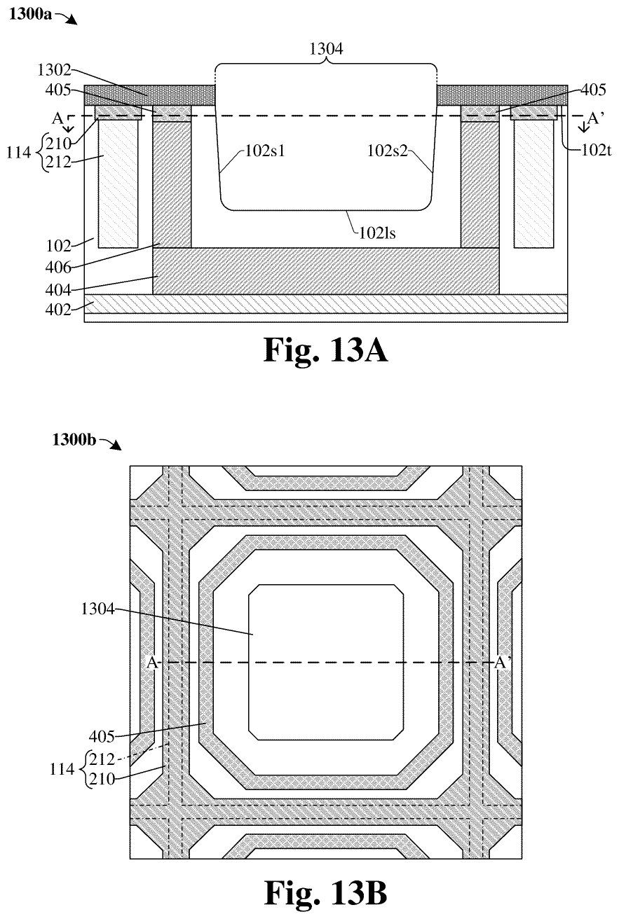

As shown in cross-sectional view 1300a and top view 1300b of FIGS. 13A-13B, a patterning process is performed on the substrate 102 to form a recess 1304 in the substrate 102. The recess 1304 is defined by opposing sidewalls 102s1, 102s2 and a lower surface 1021s of the substrate 102. In some embodiments, the patterning process includes: forming a masking layer 1302 over the substrate 102; performing an etching process on the substrate 102 with the masking layer 1302 in place; and removing the masking layer 1302. In some embodiments, the etching process includes a dry etch (e.g., a reactive-ion etch, a plasma etch, or the like) or some other suitable etch process.

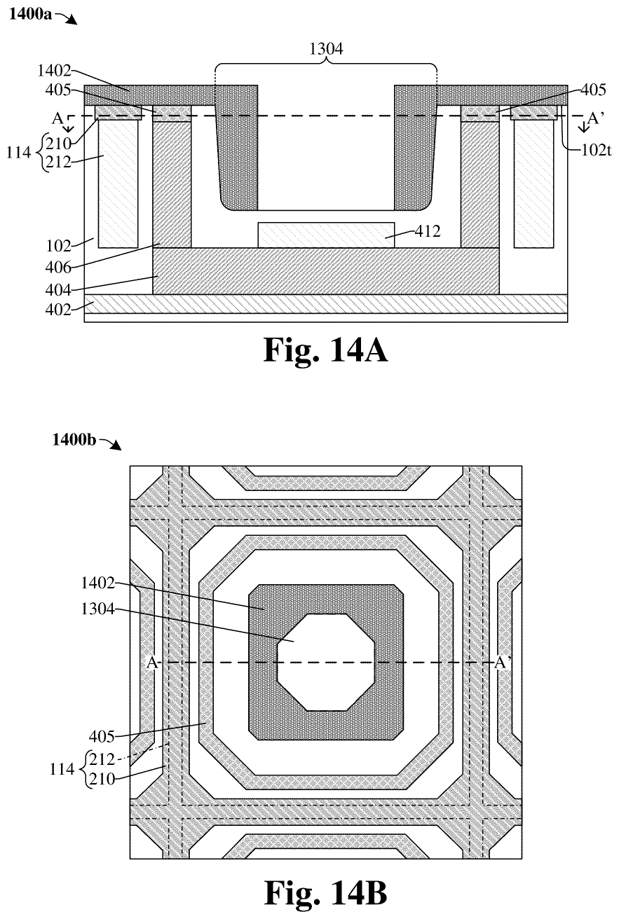

As shown in cross-sectional view 1400a and top view 1400b of FIGS. 14A-14B, a second avalanche well 412 is formed in the substrate 102 over the first avalanche well 404. In some embodiments, forming the second avalanche well 412 includes: forming an implant mask 1402 over the substrate 102; performing a doping process to implant first dopants (e.g., boron, aluminum, gallium, or the like) having the first doping type (e.g., p-type) into the substrate 102 with the implant mask 1402 in place; and removing the implant mask 1402.

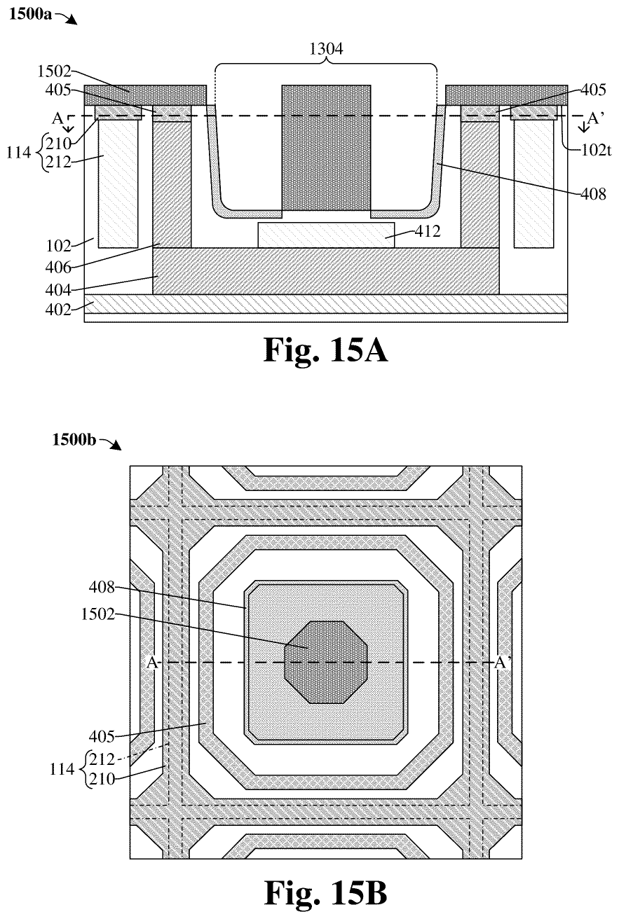

As shown in cross-sectional view 1500a and top view 1500b of FIGS. 15A-15B, a doped surface region 408 is formed in the substrate 102. In some embodiments, forming the doped surface region 408 includes: forming an implant mask 1502 over the substrate 102; performing a doping process to implant first dopants (e.g., boron, aluminum, gallium, or the like) having the first doping type (e.g., p-type) into the substrate 102 with the implant mask 1502 in place; and removing the implant mask 1502.

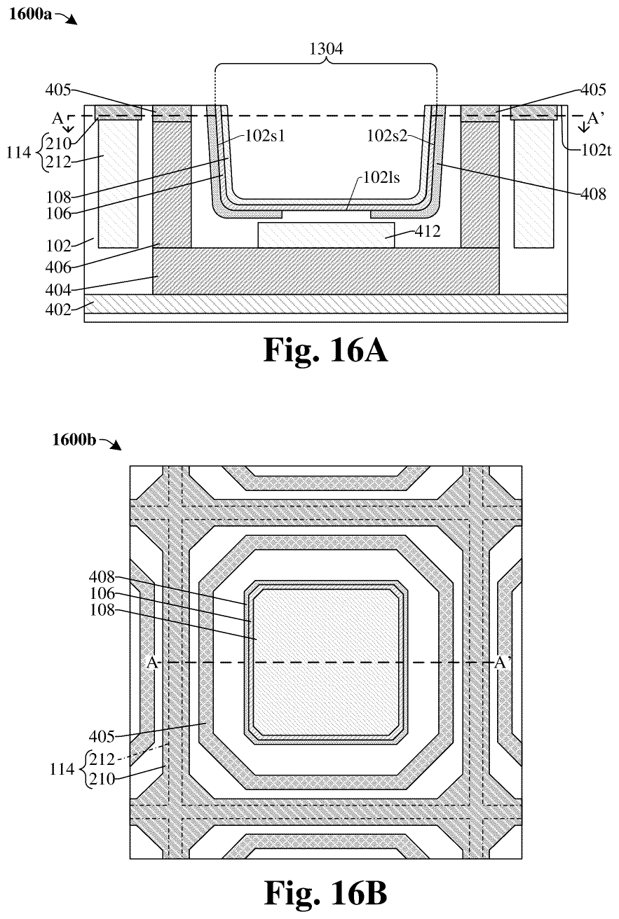

As shown in cross-sectional view 1600a and top view 1600b of FIGS. 16A-16B, an interlayer 106 and a buffer layer 108 are formed within the recess 1304. The interlayer 106 is formed along the opposing sidewalls 102s1, 102s2 and the lower surface 1021s of the substrate 102. The buffer layer 108 is formed on the interlayer 106. In some embodiments, the interlayer 106 comprises the first material (e.g., silicon) and is undoped. In some embodiments, the buffer layer 108 comprises a compound of the first material (e.g., silicon) and a second material (e.g., germanium) that is different from the first material. In various embodiments, the buffer layer 108 is undoped.

In some embodiments, the interlayer 106 is formed by a first epitaxial process that selectively grows the interlayer 106 along the surfaces of the substrate 102 defining the recess 1304. The first epitaxial process may, for example, be or comprise molecular-beam epitaxy (MBE), chemical vapor deposition (CVD), vapor-phase epitaxy (VPE), liquid-phase epitaxy (LPE), or some other suitable deposition or growth process. In some embodiments, the buffer layer 108 is formed by a second epitaxial process that selectively grows the buffer layer 108 along surfaces of the interlayer 106 in the recess 1304. The second epitaxial process may, for example, be or comprise MBE, CVD, VPE, LPE, or some other suitable deposition or growth process. In various embodiments, before forming the interlayer 106, a dielectric layer (not shown) and/or a masking layer (not shown) may be formed along the top surface 102t of the substrate 102 and is/are laterally offset from the recess 1304. In such embodiments, the dielectric layer and/or masking layer facilitates selectively forming the interlayer 106 in the recess 1304 because the interlayer 106 preferentially grows on semiconductor surfaces and not on dielectric surfaces. Further, the dielectric layer and/or masking layer may be removed after forming the buffer layer 108.

In some embodiments, the second epitaxial process utilized to form the buffer layer 108 includes performing a CVD process with a first precursor gas (e.g., silane (SiH₄)), a second precursor gas (e.g., germane (GeH₄)), and/or a carrier gas (e.g., hydrogen (H₂)). In such embodiments, the CVD process is performed at a temperature within a range of approximately 300 to 700 degrees Celsius and a pressure within a range of approximately 5 to 60 torr. In various embodiments, during the second epitaxial process, a first flow of the first precursor gas (e.g., silane (SiH₄)) may be decreased over a duration of the second epitaxial process and a second flow of the second precursor gas (e.g., germane (GeH₄)) may be continuously increased over the duration of the second epitaxial process. In such embodiments, at a beginning of the epitaxial process, a first initial flow of the first precursor gas (e.g., silane (SiH₄)) is greater than a second initial flow of the second precursor gas (e.g., germane (GeH₄)). As a result, in some embodiments, a first concentration of the first material (e.g., silicon) in the buffer layer 108 may continuously decrease from a bottom surface of the buffer layer 108 in a first direction away from the lower surface 1021s of the substrate and a second concentration of the second material (e.g., germanium) in the buffer layer 108 may continuously increase from the bottom surface of the buffer layer 108 in the first direction.

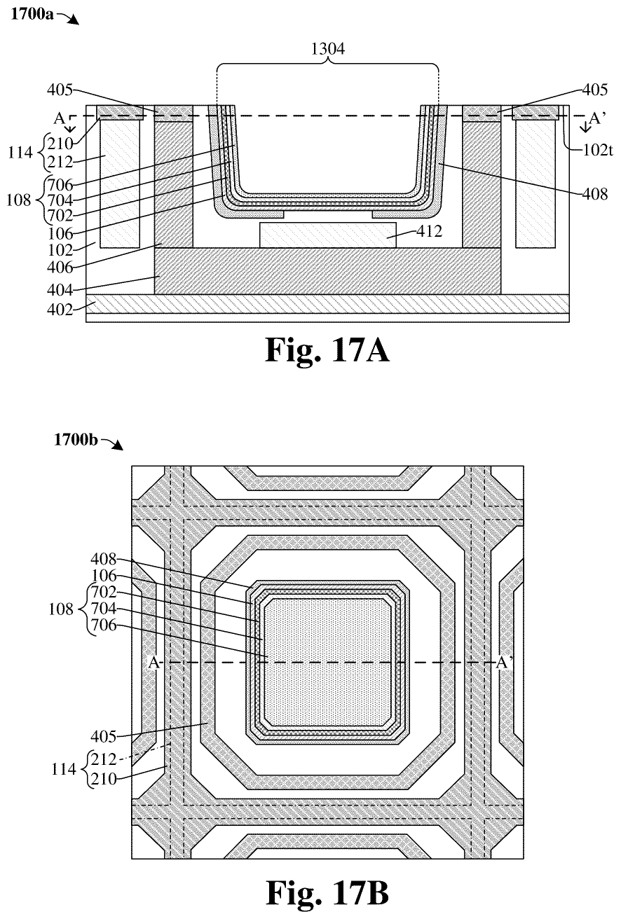

Cross-sectional view 1700a and top view 1700b of FIGS. 17A-17B illustrate an alternative embodiment of processes that may be performed in place of those in the cross-sectional view 1600a and the top view 1600b of FIGS. 16A-16B, in which the buffer layer 108 is formed comprising a first buffer film 702, a second buffer film 704, and a third buffer film 706 vertically stacked with one another. The interlayer 106 is formed along the opposing sidewalls 102s1, 102s2 and the lower surface 1021s of the substrate 102. The buffer layer 108 is formed over the interlayer 106 by: forming the first buffer film 702 on the interlayer 106; forming the second buffer film 704 on the first buffer film 702; and forming the third buffer film 706 on the second buffer film 704.

In some embodiments, the interlayer 106 is formed by a first epitaxial process that selectively grows the interlayer 106 along the surfaces of the substrate 102 defining the recess 1304. In some embodiments, a process for forming the buffer layer 108 includes: performing a second epitaxial process to form the first buffer film 702 on the interlayer 106; performing a third epitaxial process to form the second buffer film 704 on the first buffer film 702; and performing a fourth epitaxial process to form the third buffer film 706 on the second buffer film 704. In various embodiments, the first, second, third, and fourth epitaxial processes are each an individual epitaxial process that be or comprise MBE, CVD, VPE, LPE, or some other suitable deposition or growth process.

In some embodiments, the second, third, and fourth epitaxial processes may each include performing a CVD process with: a first precursor gas (e.g., silane (SiH₄)), a second precursor gas (e.g., germane (GeH₄)), and/or a carrier gas (e.g., hydrogen (H₂)) over the interlayer 106; a temperature within a range of approximately 300 to 700 degrees Celsius; and a pressure within a range of approximately 5 to 60 torr. In various embodiments, flows of the first precursor gas and the second precursor gas during the second, third, and fourth epitaxial processes are different from one another, such that the first, second, and third buffer films 702, 704, 706 each have different concentrations of the first material (e.g., silicon) and the second material (e.g., germanium) from one another. For example, a first flow of the first precursor gas (e.g., silane (SiH₄)) during the second epitaxial process is greater than a second flow of the first precursor gas (e.g., silane (SiH₄)) during the third epitaxial process, and the second flow of the first precursor gas (e.g., silane (SiH₄)) during the second epitaxial process is greater than a third flow of the first precursor gas (e.g., silane (SiH₄)) during the third epitaxial process. In some embodiments, a fourth flow of the second precursor gas (e.g., germane (GeH₄)) during the second epitaxial process is less than a fifth flow of the second precursor gas (e.g., germane (GeH₄)) during the third epitaxial process, and the fifth flow of the second precursor gas (e.g., germane (GeH₄)) during the second epitaxial process is less than a sixth flow of the second precursor gas (e.g., germane (GeH₄)) during the third epitaxial process. As a result of the different flows of the first precursor gas and the second precursor gas during the second, third, and fourth epitaxial processes, concentrations of the first and second materials in the first, second, and third buffer films 702, 704, 706 are different from one another. For example, in some embodiments, the first buffer film 702 comprises Si_{0.75}Ge_{0.25}, the second buffer film 704 comprises Si_{0.50}Ge_{0.50}, and the third buffer film 706 comprises Si_{0.25}Ge_{0.75}, however it will be appreciated that the plurality of buffer films 702-706 comprising other concentrations of the first and second materials is within the scope of the disclosure.

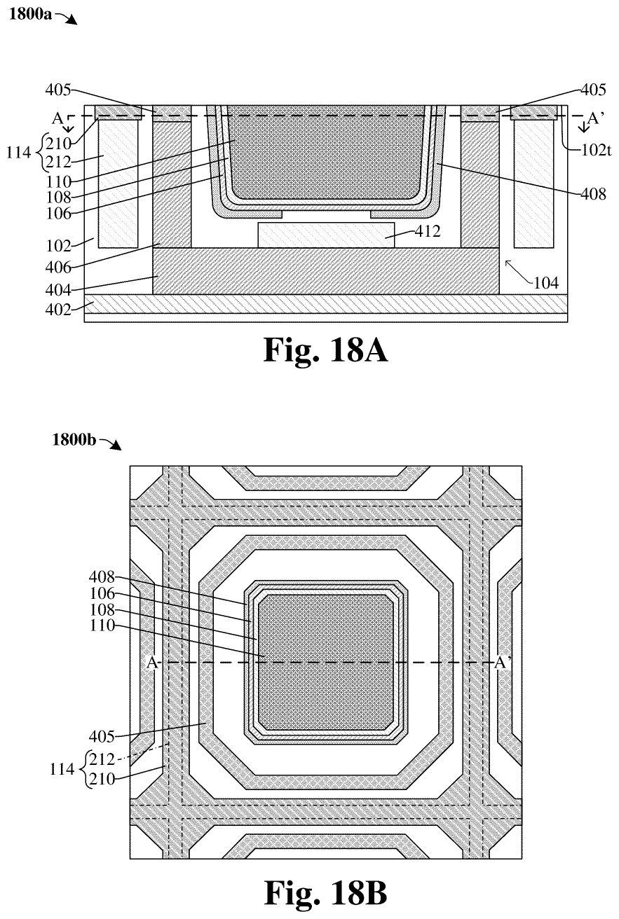

As shown in cross-sectional view 1800a and top view 1800b of FIGS. 18A-18B, a semiconductor layer 110 is formed over the buffer layer 108 and fills the recess (1304 of FIGS. 16A-16B). In some embodiments, the method of FIGS. 8A-8B through 21A-21B may flow from FIGS. 8A-8B through 16A-16B to FIGS. 18A-18B through 21A-21B or in the alternative may flow from FIGS. 8A-8B through 16A-16B to FIGS. 17A-17B through 21A-21B.

In some embodiments, a process for forming the semiconductor layer 110 includes: performing an epitaxial process to form the semiconductor layer 110 on the buffer layer 108 and performing a planarization process on the semiconductor layer 110. In some embodiments, the epitaxial process may be or comprise MBE, CVD, VPE, LPE, or some other suitable deposition or growth process. In various embodiments, the planarization process is a chemical mechanical planarization (CMP) process or some other suitable planarization process. The semiconductor layer 110 comprises the second material (e.g., germanium) different from the first material of the substrate 102. Further, the semiconductor layer 110 may be doped with the first doping type (e.g., p-type). In some embodiments, the first contact region 405, the vertical connection well 406, the first and second avalanche wells 404, 412, and the semiconductor layer 110 at least partially form a photodetector 104.

In some embodiments, the epitaxial process utilized to form the semiconductor layer 110 includes performing a CVD process with: a precursor gas (e.g., germane (GeH₄)), and/or a carrier gas (e.g., hydrogen (H₂)); a temperature within a range of approximately 300 to 700 degrees Celsius; and a pressure within a range of approximately 5 to 60 torr. In various embodiments, the epitaxial process may further include flowing a dopant precursor gas (e.g., diborane (B₂H₄)) to in-situ dope the semiconductor layer 110 with the first doping type (e.g., p-type). In various embodiments, by forming the semiconductor layer on the buffer layer 108, defects between the substrate 102 and the semiconductor layer 110 may be decreased and a crystalline quality of the semiconductor layer 110 may be increased, thereby increasing a performance of the photodetector 104.

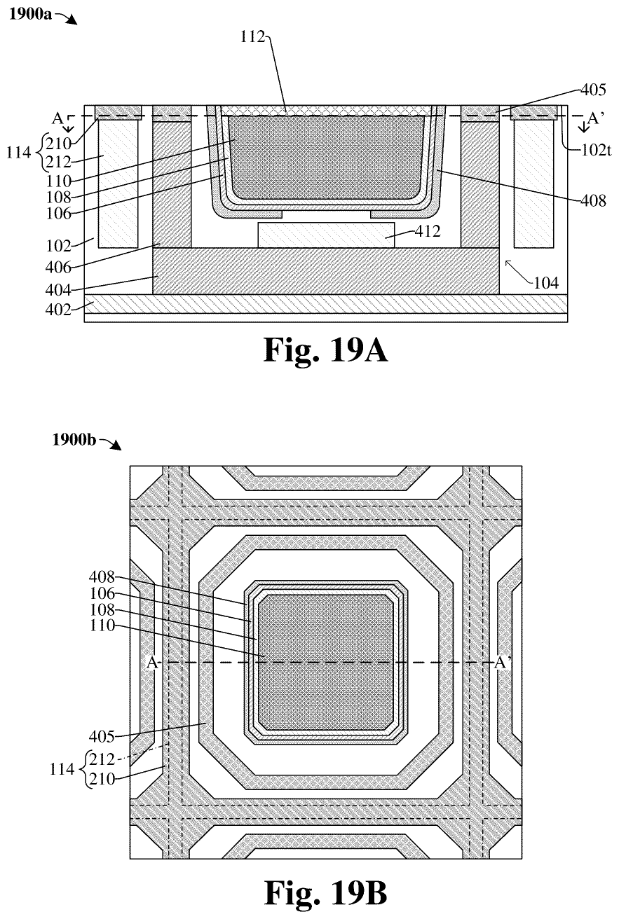

As shown in cross-sectional view 1900a and top view 1900b of FIGS. 19A-19B, a passivation layer 112 is formed on the semiconductor layer 110 and the buffer layer 108. In some embodiments, a process for forming the passivation layer 112 includes: performing an etch process (e.g., a dry etch and/or a wet etch) on the buffer layer 108 and the semiconductor layer 110 to recess top surfaces of the buffer layer 108 and the semiconductor layer 110 below the top surface 102t of the substrate; performing an epitaxial process (e.g., MBE, CVD, VPE, LPE, etc.) to form the passivation layer 112 over the substrate 102, the buffer layer 108, and the semiconductor layer 110; and performing a planarization process (e.g., a CMP process) into the passivation layer 112.

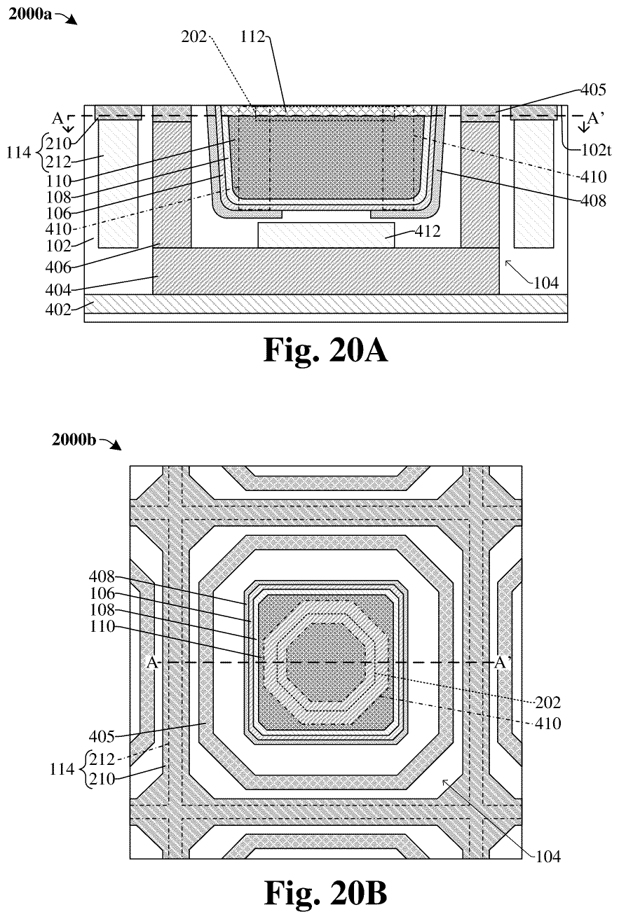

As shown in cross-sectional view 2000a and top view 2000b of FIGS. 20A-20B, a guard ring region 410 and a second contact region 202 are formed in the passivation layer 112 and the semiconductor layer 110. In some embodiments, the guard ring region 410 is formed before the second contact region 202. It will be appreciated that the second contact region 202 and the guard ring region 410 are represented in phantom in the cross-sectional view 2000a of FIG. 20A for ease of illustration. In various embodiments, the second contact region 202 continuously extends from a top surface of the passivation layer 112 into the semiconductor layer 110. In some embodiments, the guard ring region 410 continuously extends from a top surface of the passivation layer 112 through the semiconductor layer 110 and the buffer layer 108 to a bottom surface of the interlayer 106.

In some embodiments, forming the guard ring region 410 includes: forming a first implant mask (not shown) over the substrate 102; performing a first doping process to implant first dopants (e.g., boron, aluminum, gallium, or the like) having the first doping type (e.g., p-type) into the semiconductor layer 110 with the first implant mask in place; and removing the first implant mask. In various embodiments, forming the second contact region 202 includes: forming a second implant mask (not shown) over the substrate 102; performing a doping process to implant first dopants (e.g., boron, aluminum, gallium, or the like) having the first doping type (e.g., p-type) into the semiconductor layer 110 with the second implant mask in place; and removing the second implant mask. In some embodiments, a doping concentration of the second contact region 202 is greater than a doping concentration of the guard ring region 410.

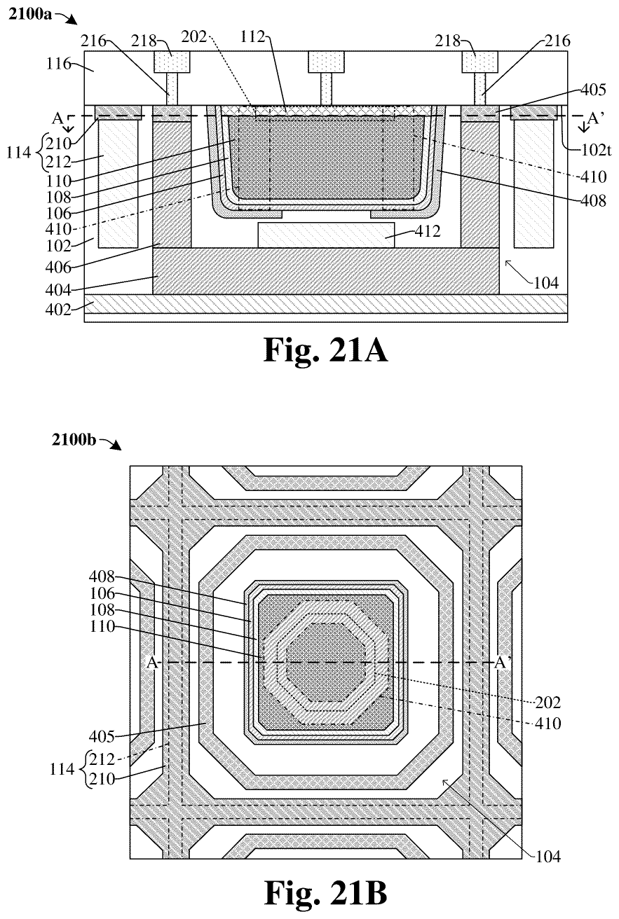

As shown in cross-sectional view 2100a and top view 2100b of FIGS. 21A-21B, a dielectric structure 116, a plurality of conductive contacts 216, and a plurality of conductive wires 218 are formed over the substrate 102. The plurality of conductive contacts 216 are formed in the dielectric structure 116. The plurality of conductive wires 218 are formed in the dielectric structure 116 over the plurality of conductive contacts 216.

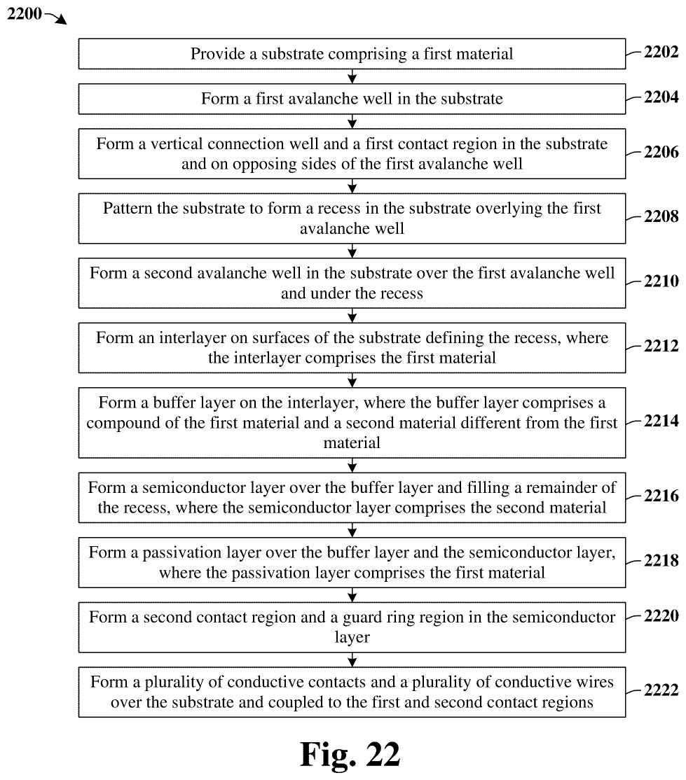

FIG. 22 illustrates a flow diagram of some embodiments of a method 2200 of forming an IC comprising a buffer layer disposed between a substrate and a semiconductor layer of a photodetector. Although the method 2200 is illustrated and/or described as a series of acts or events, it will be appreciated that the method 2200 is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2202, a substrate comprising a first material is provided. FIGS. 8A-8B illustrate various views corresponding to some embodiments of act 2202.

At act 2204, a first avalanche well is formed in the substrate. FIGS. 8A-8B illustrate various views corresponding to some embodiments of act 2204.

At act 2206, a vertical connection well and a first contact region are formed in the substrate on opposing sides of the first avalanche well. FIGS. 9A-9B and 11A-11B illustrate various views corresponding to some embodiments of act 2206.

At act 2208, the substrate is patterned to form a recess in the substrate overlying the first avalanche well. FIGS. 13A-13B illustrate various views corresponding to some embodiments of act 2208.

At act 2210, a second avalanche well is formed in the substrate over the first avalanche well and under the recess. FIGS. 14A-14B illustrate various views corresponding to some embodiments of act 2210.

At act 2212, an interlayer is formed on surfaces of the substrate defining the recess, where the interlayer comprises the first material. FIGS. 16A-16B illustrate various views corresponding to some embodiments of act 2212. Further, FIGS. 17A-17B illustrate various views corresponding to some other embodiments of act 2212.

At act 2214, a buffer layer is formed on the interlayer. The buffer layer comprises a compound of the first material and a second material different from the first material. FIGS. 16A-16B illustrate various views corresponding to some embodiments of act 2214. Further, FIGS. 17A-17B illustrate various views corresponding to some other embodiments of act 2214.

At act 2216, a semiconductor layer is formed over the buffer layer and fills a remainder of the recess. The semiconductor layer comprises the second material. FIGS. 18A-18B illustrate various views corresponding to some embodiments of act 2216.

At act 2218, a passivation layer is formed over the buffer layer and the semiconductor layer. The passivation layer comprises the first material. FIGS. 19A-19B illustrate various views corresponding to some embodiments of act 2218.

At act 2220, a second contact region and a guard ring region are formed in the semiconductor layer. FIGS. 20A-20B illustrate various views corresponding to some embodiments of act 2220.

At act 2222, a plurality of conductive contacts and a plurality of conductive wires are formed over the substrate and are coupled to the first and second contact regions. FIGS. 21A-21B illustrate various views corresponding to some embodiments of act 2222.

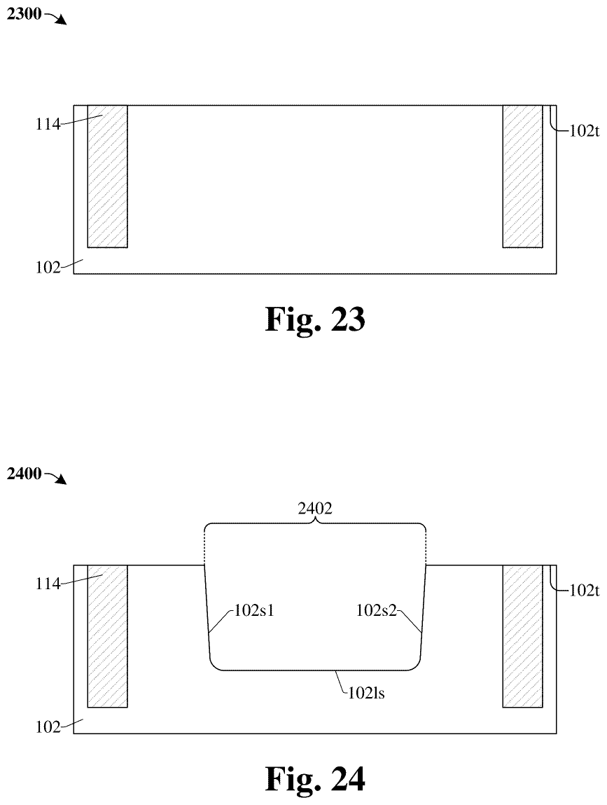

FIGS. 23-29 illustrate a series of cross-sectional views 2300-2900 of some other embodiments of a method for forming an integrated chip (IC) comprising a buffer layer disposed between a substrate and a semiconductor layer of a photodetector. Although the cross-sectional views 2300-2900 shown in FIGS. 23-29 are described with reference to a method of forming the IC, it will be appreciated that the structures shown in FIGS. 23-29 are not limited to the method of formation but rather may stand alone separate of the method. Furthermore, although FIGS. 23-29 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 2300 of FIG. 23, the isolation structure 114 is formed in the substrate 102. In some embodiments, the substrate 102 comprises the first material (e.g., silicon) and has the first doping type (e.g., p-type). In some embodiments, forming the isolation structure 114 includes: forming a masking layer (not shown) over the top surface 102t of the substrate 102; etching the substrate 102 with the masking layer in place to form one or more trenches extending into the substrate 102; depositing (e.g., by CVD, physical vapor deposition (PVD), atomic layer deposition (ALD)) an isolation material (e.g., one or more dielectric materials such as silicon dioxide, silicon nitride, silicon carbide, or the like) in the one or more trenches; and performing a planarization process (e.g., a CMP process) on the isolation material. In various embodiments, the masking layer may be removed before or after depositing the isolation material in the one or more trenches.

As shown in the cross-sectional view 2400 of FIG. 24, a recess 2402 is formed in the substrate 102. The recess 2402 may be formed by, for example, the acts illustrated and/or described in FIGS. 13A-13B.

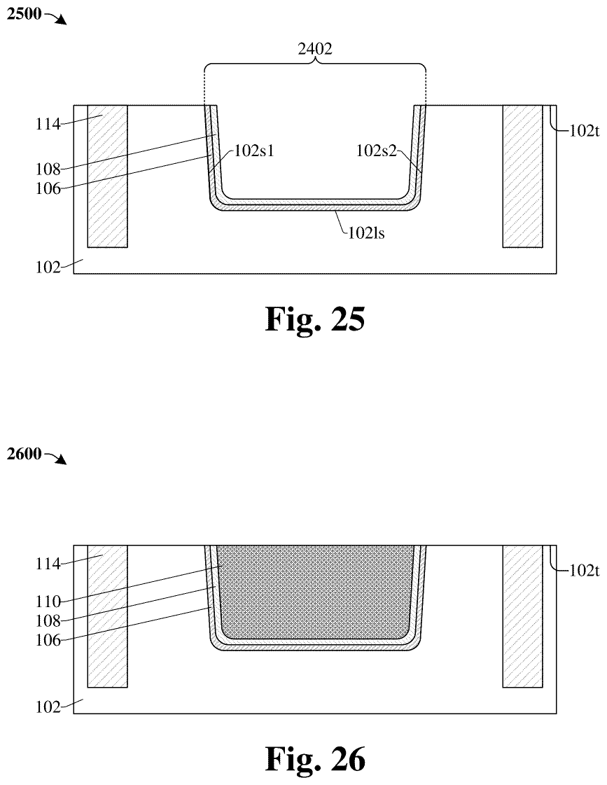

As shown in the cross-sectional view 2500 of FIG. 25, the interlayer 106 and the buffer layer 108 are formed lining the recess 2402. In some embodiments, the interlayer 106 and the buffer layer 108 may be formed by, for example, the acts illustrated and/or described in FIGS. 16A-16B. In other embodiments, the interlayer 106 and the buffer layer 108 may be formed by, for example, the acts illustrated and/or described in FIGS. 17A-17B. In various embodiments, the buffer layer 108 comprises a compound of the first material and the second material, and the interlayer 106 comprises the first material.

As shown in the cross-sectional view 2600 of FIG. 26, the semiconductor layer 110 is formed in the recess (2402 of FIG. 25) over the buffer layer 108. The semiconductor layer 110 comprises the second material. The semiconductor layer 110 may be formed by, for example, the acts illustrated and/or described in FIGS. 18A-18B.

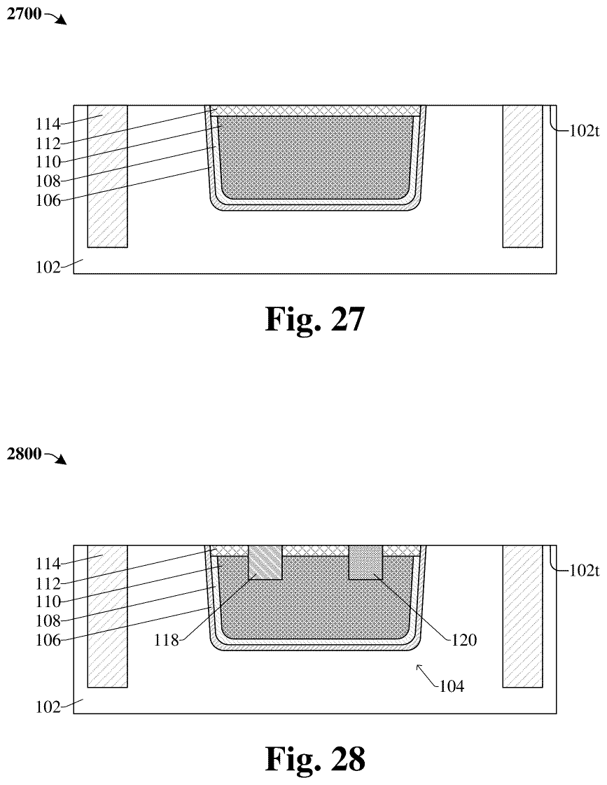

As shown in the cross-sectional view 2700 of FIG. 27, the passivation layer 112 is formed over the buffer layer 108 and the semiconductor layer 110. The passivation layer 112 may be formed by, for example, the acts illustrates and/or described in FIGS. 19A-19B.

As shown in the cross-sectional view 2800 of FIG. 28, a first doped region 118 and a second doped region 120 are formed in the passivation layer 112 and the semiconductor layer 110. In some embodiments, forming the first doped region 118 includes: forming a first implant mask (not shown) over the substrate 102; performing a first doping process to implant first dopants (e.g., boron, aluminum, gallium, or the like) having the first doping type (e.g., p-type) into the semiconductor layer 110 with the first implant mask in place; and removing the first implant mask. In some embodiments, forming the second doped region 120 includes: forming a second implant mask over the substrate 102; performing a second doping process to implant second dopants (e.g., arsenic, antimony, phosphorus, or the like) having the second doping type (e.g., n-type) into the semiconductor layer 110 with the second implant mask in place; and removing the second implant mask.

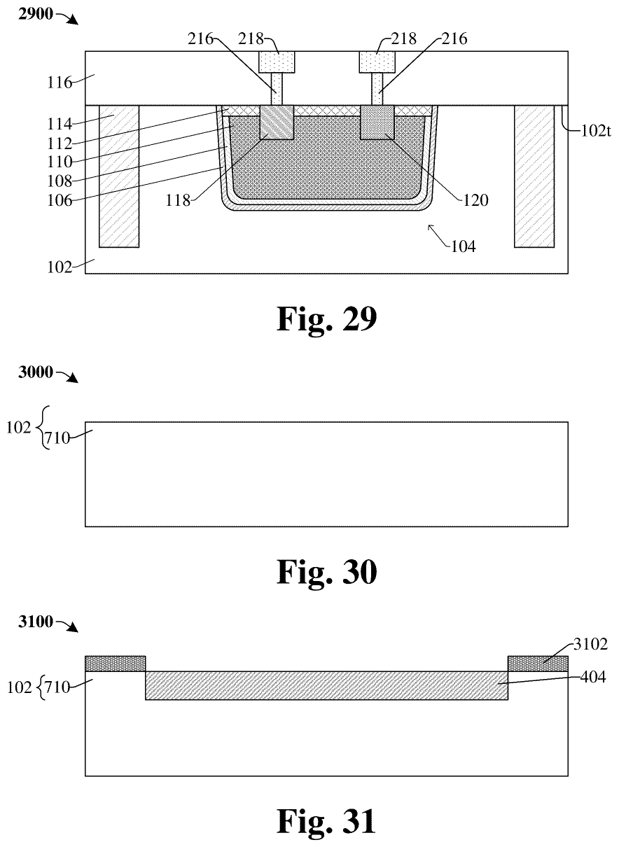

As shown in the cross-sectional view 2900 of FIG. 29, the dielectric structure 116, the plurality of conductive contacts 216, and the plurality of conductive wires 218 are formed over the substrate 102. The plurality of conductive contacts 216 are formed in the dielectric structure 116. The plurality of conductive wires 218 are formed in the dielectric structure 116 over the plurality of conductive contacts 216.

FIGS. 30-42 illustrate a series of cross-sectional views 3000-4200 of some other embodiments of a method for forming an integrated chip (IC) comprising a buffer layer disposed between a substrate and a semiconductor layer of a photodetector. Although the cross-sectional views 3000-4200 shown in FIGS. 30-42 are described with reference to a method of forming the IC, it will be appreciated that the structures shown in FIGS. 30-42 are not limited to the method of formation but rather may stand alone separate of the method. Further, although FIGS. 30-42 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in cross-sectional view 3000 of FIG. 30, a base substrate 710 of a substrate 102 is provided. The base substrate 710 may, for example, be or comprise silicon, monocrystalline silicon, a silicon-on-insulator (SOI) substrate, or some other suitable semiconductor substrate material. In various embodiments, the base substrate 710 has the first doping type (e.g., p-type).

As shown in cross-sectional view 3100 of FIG. 31, a first avalanche well 404 is formed in the base substrate 710. In some embodiments, forming the first avalanche well 404 includes: forming an implant mask 3102 over the base substrate 710; performing a doping process to implant second dopants (e.g., arsenic, antimony, phosphorus, or the like) having the second doping type (e.g., n-type) into the base substrate 710 with the implant mask 3102 in place; and removing the implant mask 3102. In some embodiments, the first avalanche well 404 has a doping concentration within a range of approximately 1e17 to 1e18 atoms/cm³ or some other suitable value.

As shown in cross-sectional view 3200 of FIG. 32, an upper substrate layer 712 of the substrate 102 is formed on the base substrate 710. The upper substrate layer 712 may, for example, be formed by MBE, CVD, VPE, LPE, or some other suitable deposition or growth process. The upper substrate layer 712 comprises the first material (e.g., silicon). In some embodiments, the upper substrate layer 712 has the first doping type (e.g., p-type).

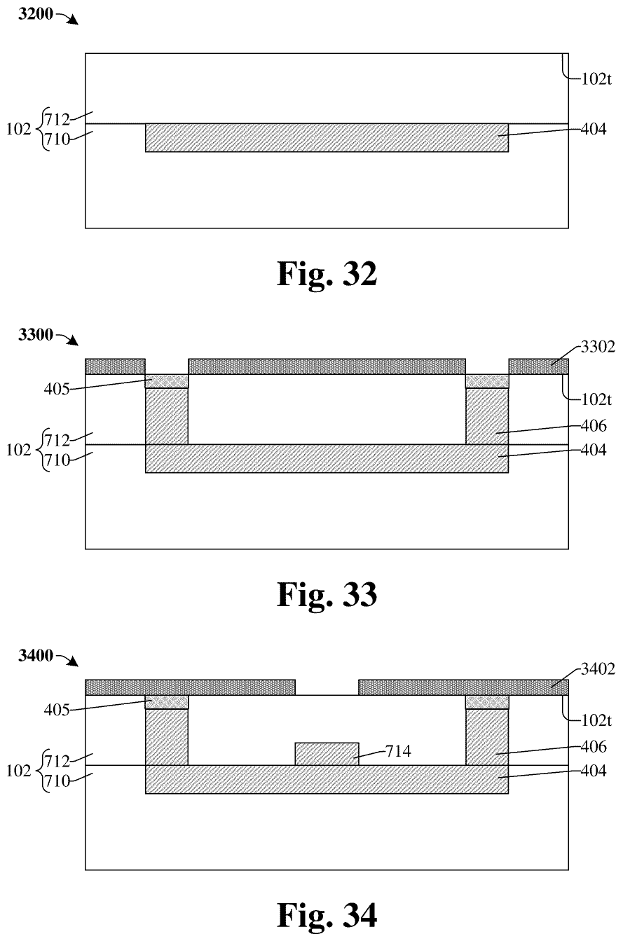

As shown in cross-sectional view 3300 of FIG. 33, a vertical connection well 406 and a first contact region 405 are formed in the substrate 102. In some embodiments, forming the vertical connection well 406 and the first contact region 405 includes: forming an implant mask 3302 over the substrate 102; performing a first doping process to implant second dopants (e.g., arsenic, antimony, phosphorus, or the like) having the second doping type (e.g., n-type) into the upper substrate layer 712 with the implant mask 3302 in place, thereby defining or forming the vertical connection well 406; performing a second doping process to implant second dopants (e.g., arsenic, antimony, phosphorus, or the like) having the second doping type (e.g., n-type) into the upper substrate layer 712 with the implant mask 3302 in place, thereby defining or forming the first contact region 405; and removing the implant mask 3302. In some embodiments, a doping concentration of the first contact region 405 is greater than a doping concentration of the vertical connection well 406. The doping concentration of the first contact region 405 may, for example, be within a range of approximately 1e19 to 1e20 atoms/cm³ or some other suitable value. The doping concentration of the vertical connection well 406 may, for example, be within a range of approximately 1e16 to 1e17 atoms/cm³ or some other suitable value.

As shown in cross-sectional view 3400 of FIG. 34, an avalanche well extension region 714 is formed in the substrate 102. In some embodiments, forming the avalanche well extension region 714 includes: forming an implant mask 3402 over the substrate 102; performing a doping process to implant second dopants (e.g., arsenic, antimony, phosphorus, or the like) having the second doping type (e.g., n-type) into the substrate 102 with the implant mask 3402 in place; and removing the implant mask 3402. A doping concentration of the avalanche well extension region 714 may, for example, be within a range of approximately 1e17 to 1e18 atoms/cm³ or some other suitable value. In some embodiments, the doping concentration of the avalanche well extension region 714 is equal to the doping concentration of the first avalanche well 404.

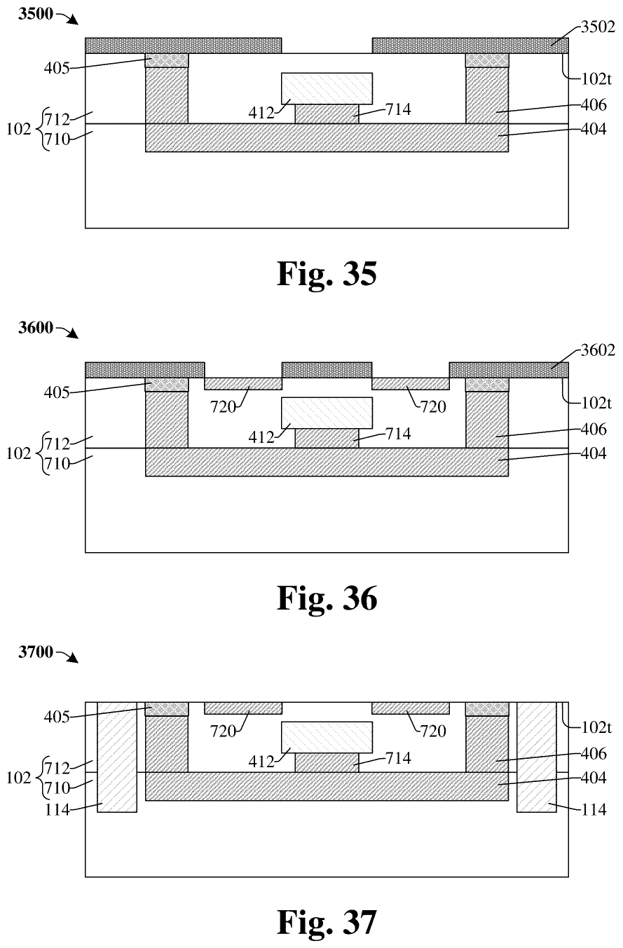

As shown in cross-sectional view 3500 of FIG. 35, a second avalanche well 412 is formed in the substrate 102. In some embodiments, forming the second avalanche well 412 includes: forming an implant mask 3502 over the substrate 102; performing a doping process to implant first dopants (e.g., boron, aluminum, gallium, or the like) having the first doping type (e.g., p-type) into the upper substrate layer 712 with the implant mask 3502 in place; and removing the implant mask 3502. A doping concentration of the second avalanche well 412 may, for example, be within a range of approximately 1e16 to 1e17 atoms/cm³ or some other suitable value. In some embodiments, the doping concentration of the second avalanche well 412 is less than the doping concentration of the avalanche well extension region 714.

As shown in cross-sectional view 3600 of FIG. 36, an upper doped surface region 720 is formed in the substrate 102. In some embodiments, forming the upper doped surface region 720 includes: forming an implant mask 3602 over the substrate 102; performing a doping process to implant first dopants (e.g., boron, aluminum, gallium, or the like) having the first doping type (e.g., p-type) into the substrate 102 with the implant mask 3602 in place; and removing the implant mask 3602. A doping concentration of the upper doped surface region 720 may, for example, be within a range of approximately 1e15 to 1e17 atoms/cm³ or some other suitable value.

As shown in cross-sectional view 3700 of FIG. 37, an isolation structure 114 is formed in the substrate 102 on opposing sides of the first avalanche well 404. In some embodiments, the isolation structure 114 is formed as illustrated and/or described in FIGS. 10A-10B and 12A-12B or in FIG. 23.

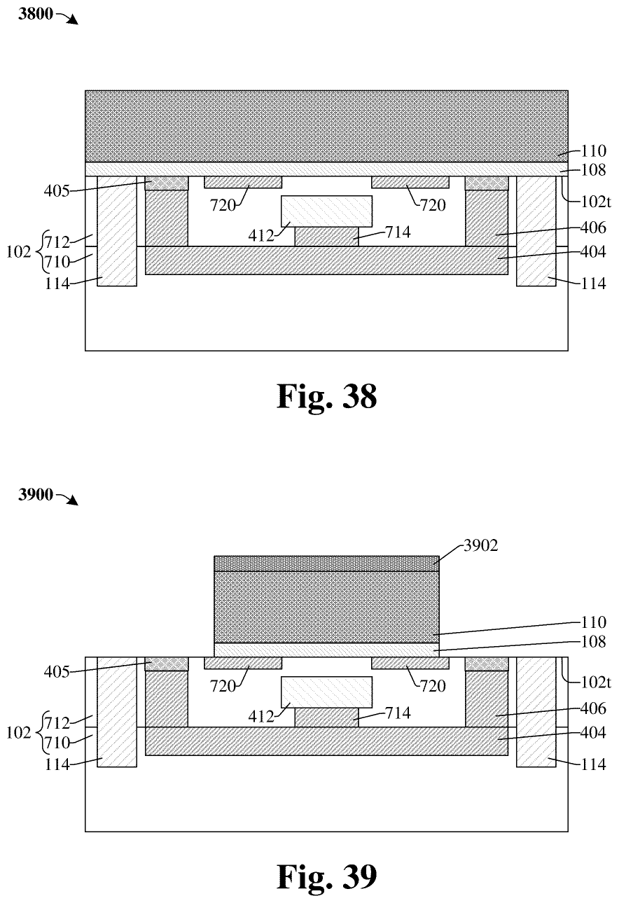

As shown in cross-sectional view 3800 of FIG. 38, a buffer layer 108 and a semiconductor layer 110 are formed on a top surface 102t of the substrate 102. In some embodiments, the buffer layer 108 comprises a compound of the first material (e.g., silicon) and a second material (e.g., germanium) that is different from the first material. In various embodiments, the buffer layer 108 is undoped. The buffer layer 108 may be deposited on the substrate 102 by an epitaxial process such as, for example, MBE, CVD, VPE, LPE, or some other suitable deposition or growth process. In various embodiments, the epitaxial process used to form the buffer layer 108 may be configured as the second epitaxial process described in FIGS. 16A-16B. In other embodiments, the buffer layer 108 may be formed as illustrated and/or described in FIGS. 17A-17B. The semiconductor layer 110 is formed on the buffer layer 108. In some embodiments, the semiconductor layer 110 is deposited by, for example, MBE, CVD, VPE, LPE, or some other suitable deposition or growth process. The semiconductor layer 110 comprises the second material (e.g., germanium).

As shown in cross-sectional view 3900 of FIG. 39, a patterning process is performed on the buffer layer 108 and the semiconductor layer 110. In some embodiments, the patterning process includes: forming a masking layer 3902 on the semiconductor layer 110; performing an etch process (e.g., a plasma etch, a reactive-ion etch, etc.) on the buffer layer 108 and the semiconductor layer 110; and removing the masking layer 3902.

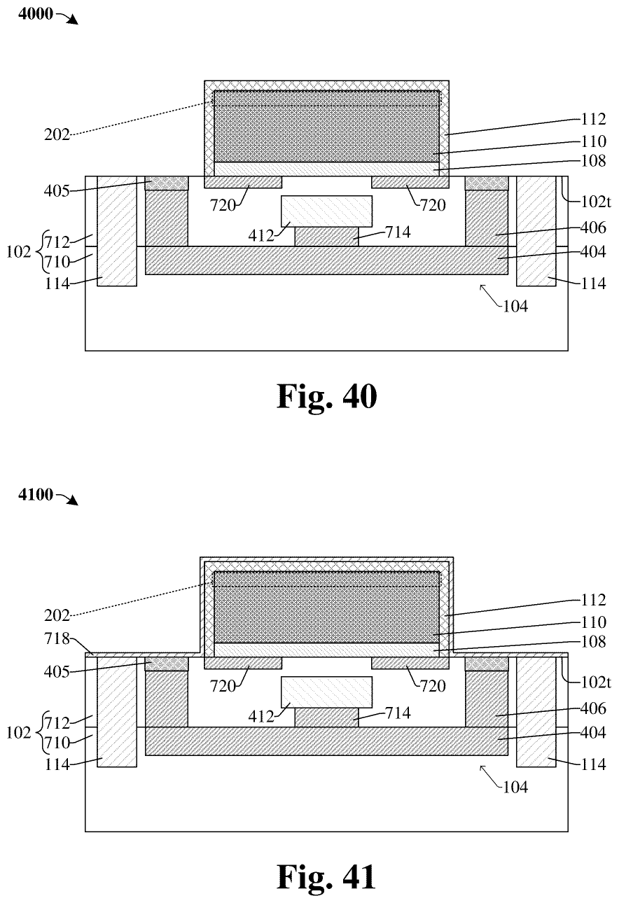

As shown in cross-sectional view 4000 of FIG. 40, a passivation layer 112 is formed over the semiconductor layer 110 and the buffer layer 108. In some embodiments, a process for forming the passivation layer 112 includes: depositing or growing (e.g., by MBE, CVD, VPE, LPE, etc.) the passivation layer 112 over the substrate 102 and the semiconductor layer 110 and performing an etch process (e.g., a plasma etch, a reactive ion etch, or some other suitable etch) on the passivation layer 112 to remove portions of the passivation layer 112 in regions of the substrate 102 offset from the semiconductor layer 110. In various embodiments, the passivation layer 112 directly contacts a top surface and outer sidewalls of the semiconductor layer 110 and outer sidewalls of the buffer layer 108. In some embodiments, a bottom surface of the passivation layer 112 is aligned with a bottom surface of the buffer layer 108.

Further, as shown in FIG. 40, a second contact region 202 is formed in the semiconductor layer 110 and/or the passivation layer 112. In some embodiments, forming the second contact region 202 includes: forming an implant mask (not shown) over the substrate 102; performing a doping process to implant first dopants (e.g., boron, aluminum, gallium, or the like) having the first doping type (e.g., p-type) into the semiconductor layer 110 and/or the passivation layer 112; and removing the implant mask. It will be appreciated that the second contact region 202 is represented in phantom in the cross-sectional view 4000 of FIG. 40 for case of illustration. In some embodiments, the first contact region 405, the vertical connection well 406, the first and second avalanche wells 404, 412, the avalanche well extension region 714, and the semiconductor layer 110 at least partially form a photodetector 104.

As shown in cross-sectional view 4100 of FIG. 41, an etch stop layer 718 is formed over the substrate 102. In some embodiments, the etch stop layer 718 is formed over the substrate 102 by, for example, a PVD process, a CVD process, an ALD process, or some other suitable growth or deposition process. In various embodiments, the etch stop layer 718 is formed with a thickness less than that of the passivation layer 112. Further, the etch stop layer 718 is formed along opposing sidewalls and a top surface of the passivation layer 112. In some embodiments, a bottom surface of the etch stop layer 718 is aligned with the bottom surface of the passivation layer 112 and the bottom surface of the buffer layer 108.

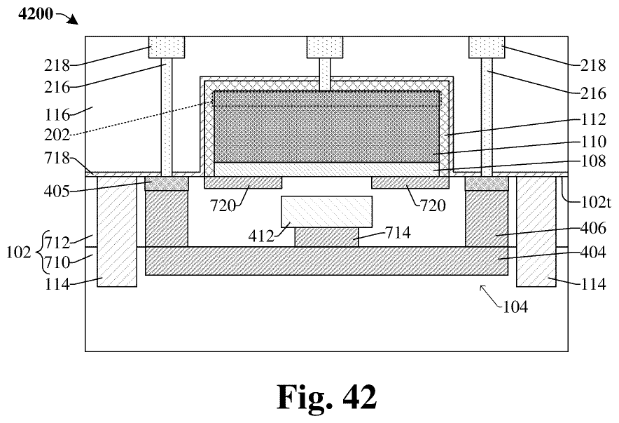

As shown in cross-sectional view 4200 of FIG. 42, a dielectric structure 116, a plurality of conductive contacts 216, and a plurality of conductive wires 218 are formed over the substrate 102.

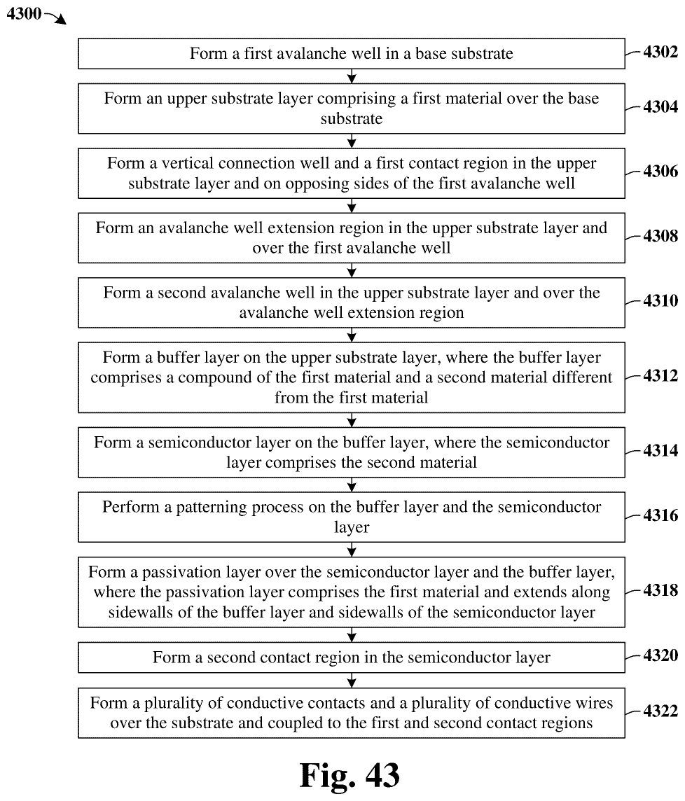

FIG. 43 illustrates a flow diagram of some embodiments of a method 4300 of forming an IC comprising a buffer layer disposed between a substrate and a semiconductor layer of a photodetector. Although the method 4300 is illustrated and/or described as a series of acts or events, it will be appreciated that the method 4300 is not limited to the illustrated ordering or acts. Thus, in some embodiments, the acts may be carried out in different orders than illustrated and/or may be carried out concurrently. Further, in some embodiments, the illustrated acts or events may be subdivided into multiple acts or events, which may be carried out a separate times or concurrently with other acts or sub-acts. In some embodiments, some illustrated acts or events may be omitted, and other un-illustrated acts or events may be included.

At act 4302, a first avalanche well is formed in a base substrate. FIG. 31 illustrates a cross-sectional view 3100 corresponding to some embodiments of act 4302.

At act 4304, an upper substrate layer comprising a first material is formed over the base substrate. FIG. 32 illustrates a cross-sectional view 3200 corresponding to some embodiments of act 4304.

At act 4306, a vertical connection well and a first contact region are formed in the upper substrate layer and on opposing sides of the first avalanche well. FIG. 33 illustrates a cross-sectional view 3300 corresponding to some embodiments of act 4306.

At act 4308, an avalanche well extension region is formed in the upper substrate layer and over the first avalanche well. FIG. 34 illustrates a cross-sectional view 3400 corresponding to some embodiments of act 4308.

At act 4310, a second avalanche well is formed in the upper substrate layer and over the avalanche well extension region. FIG. 35 illustrates a cross-sectional view 3500 corresponding to some embodiments of act 4310.

At act 4312, a buffer layer is formed on the upper substrate layer, where the buffer layer comprises a compound of the first material and a second material different from the first material. FIG. 38 illustrates a cross-sectional view 3800 corresponding to some embodiments of act 4312.

At act 4314, a semiconductor layer is formed on the buffer layer, there the semiconductor layer comprises the second material. FIG. 38 illustrates the cross-sectional view 3800 corresponding to some embodiments of act 4314.

At act 4316, a patterning process is performed on the buffer layer and the semiconductor layer. FIG. 39 illustrates a cross-sectional view 3900 corresponding to some embodiments of act 4316.

At act 4318, a passivation layer is formed over the semiconductor layer and the buffer layer. The passivation layer comprises the first material and extends along sidewalls of the buffer layer and sidewalls of the semiconductor layer. FIG. 40 illustrates a cross-sectional view 4000 corresponding to some embodiments of act 4318.

At act 4320, a second contact region is formed in the semiconductor layer. FIG. 40 illustrates the cross-sectional view 4000 corresponding to some embodiments of act 4320.

At act 4322, a plurality of conductive contacts and a plurality of conductive wires are formed over the substrate and are coupled to the first and second contact regions. FIG. 42 illustrates a cross-sectional view 4200 corresponding to some embodiments of act 4322.

Accordingly, in some embodiments, the present disclosure relates to an integrated chip (IC) comprising a buffer layer disposed between a substrate and a semiconductor layer of a photodetector, where the substrate comprises a first material and the semiconductor layer comprises a second material different from the first material. The buffer layer comprises a compound of the first material and the second material.

In some embodiments, the present application provides an integrated chip (IC). The IC includes a substrate comprising a first material; a semiconductor layer on the substrate and comprising a second material different from the first material; and a buffer layer arranged between the semiconductor layer and the substrate, wherein the buffer layer comprises the first material and the second material. In some embodiments, the first material is silicon and the second material is germanium. In some embodiments, the buffer layer comprises a first buffer film, a second buffer film, and a third buffer film, wherein the first buffer film is arranged between the substrate and the second buffer film, wherein the third buffer film is arranged between the second buffer film and the semiconductor layer, wherein a concentration of the first material in the first buffer film is greater than a concentration of the first material in the second buffer film and a concentration of the first material in the third buffer film is less than the concentration of the first material in the second buffer film. In some embodiments, a concentration of the second material in the first buffer film is less than a concentration of the second material in the second buffer film and a concentration of the second material in the third buffer film is greater than the concentration of the second material in the second buffer film, wherein a thickness of the first buffer film is less than a thickness of the second buffer film and a thickness of the third buffer film is greater than the thickness of the second buffer film. In some embodiments, a first concentration of the first material in the buffer layer discretely decreases at least three times in a first direction from the substrate towards the semiconductor layer, wherein a second concentration of the second material in the buffer layer discretely increases at least three times in the first direction. In some embodiments, a ratio of a thickness of the buffer layer to a thickness of the semiconductor layer is within a range of 0.01 to 0.10. In some embodiments, the substrate comprises opposing sidewalls defining a recess, wherein the semiconductor layer is arranged in the recess, wherein the IC further includes an interlayer arranged in the recess between the buffer layer and the substrate, wherein the interlayer comprises the first material. In some embodiments, the IC further includes a passivation layer over a top surface of the semiconductor layer and a top surface of the buffer layer, wherein the passivation layer contacts inner sidewalls of the interlayer and has a top surface aligned with a top surface of the substrate, wherein the passivation layer comprises the first material. In some embodiments, the IC further includes a plurality of first contact regions disposed in the substrate and laterally offset from the interlayer, wherein the first contact regions are spaced on opposing sides of the semiconductor layer; a second contact region disposed in the semiconductor layer; and a plurality of outer lateral wells disposed in the substrate and underlying the plurality of first contact regions, wherein the outer lateral wells continuously laterally extend from under a corresponding first contact region, through the interlayer and the buffer layer, to the semiconductor layer, wherein a doping type of the first contact regions and the outer lateral wells is different from a doping type of the second contact region.

In some embodiments, the present application provides an IC. The IC includes a substrate comprising an upper surface; a germanium layer over the upper surface of the substrate; an isolation structure disposed in the substrate and on opposing sides of the germanium layer; a buffer layer disposed between the upper surface of the substrate and the germanium layer, wherein the buffer layer comprises silicon and germanium; and passivation layer contacting a top surface of the germanium layer, wherein the passivation layer comprises epitaxial silicon. In some embodiments, a lattice constant of the buffer layer discretely increases at least two times from a bottom surface of the buffer layer in a direction towards a bottom surface of the germanium layer. In some embodiments, a concentration of germanium in the buffer layer continuously increases from a bottom surface of the buffer layer in a first direction towards a bottom surface of the germanium layer, wherein a concentration of silicon in the buffer layer continuously decreases from the bottom surface of the buffer layer in the first direction. In some embodiments, the substrate comprises a first doping type, wherein the IC further comprises: a first avalanche well disposed in the substrate and under the germanium layer, wherein the first avalanche well comprises a second doping type opposite the first doping type; a first contact region disposed in the substrate and laterally wrapped around the germanium layer, wherein the first contact region is offset from the buffer layer and comprises the second doping type; a vertical connection well disposed in the substrate and continuously extending from the first contact region to the first avalanche well, wherein the vertical connection well comprises the second doping type; and a second avalanche well disposed in the substrate and between the germanium layer and the second avalanche well, wherein the second avalanche well comprises the first doping type. In some embodiments, the substrate comprises opposing sidewalls extending from a top surface of the substrate to the upper surface and defining a recess, wherein the germanium layer and the buffer layer are disposed in the recess, wherein the IC further comprises an interlayer contacting the opposing sidewalls of the substrate, wherein the interlayer is disposed between the substrate and the buffer layer, wherein a thickness of the interlayer is greater than a thickness of the buffer layer and a thickness of the passivation layer is greater than is greater than the thickness of the buffer layer. In some embodiments, a bottommost surface of the germanium layer is vertically above a top surface of the substrate, and wherein outer sidewalls of the germanium layer are aligned with outer sidewalls of the buffer layer. In some embodiments, the passivation layer contacts the outer sidewalls of the germanium layer and the outer sidewalls of the buffer layer, and wherein a bottom surface of the passivation layer is aligned with a bottom surface of the buffer layer.

In some embodiments, the present application provides a method for forming an IC. The method includes forming a buffer layer on a substrate, wherein the substrate comprises a first material, wherein the buffer layer comprises the first material and a second material different from the first material; forming a semiconductor layer on the buffer layer, wherein the semiconductor layer comprises the second material; and forming a passivation layer along a top surface of the semiconductor layer, wherein the passivation layer comprises the first material. In some embodiments, the method further comprises forming a first avalanche well in the substrate and below the semiconductor layer; forming a vertical connection well in the substrate and on opposing sides of the first avalanche well; forming a first contact region in the substrate and over the vertical connection well, wherein when viewed in top view the vertical connection well and the first contact region are ring-shaped; forming a second avalanche well in the substrate and over the first avalanche well; forming a second contact region in the semiconductor layer, wherein the second contact region and the second avalanche well comprise a first doping type; and wherein the first avalanche well, the vertical connection well, and the first contact region comprise a second doping type opposite the first doping type. In some embodiments, forming the buffer layer includes epitaxially growing a first buffer film on the substrate; epitaxially growing a second buffer film on the first buffer film; and epitaxially growing a third buffer film on the second buffer film, wherein concentrations of the first and second materials in the first buffer film, the second buffer film, and the third buffer film are different from one another, and wherein thicknesses of the first buffer film, the second buffer film, and the third buffer film are respectively less than a thickness of the passivation layer. In some embodiments, the method further includes performing a first etch into the substrate to form a recess; forming an interlayer lining the recess, wherein the interlayer comprises the first material, wherein the interlayer is formed by a first epitaxial process and the buffer layer is formed by a second epitaxial process, wherein a thickness of the interlayer is greater than a thickness of the buffer layer; and wherein the buffer layer is formed on the interlayer in the recess, wherein the semiconductor layer is formed in the recess.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip (IC), comprising:
a substrate comprising a first material;
a semiconductor layer on the substrate and comprising a second material different from the first material; and
a buffer layer arranged between the semiconductor layer and the substrate, wherein the buffer layer comprises the first material and the second material.

2. The IC of claim 1, wherein the first material is silicon and the second material is germanium.

3. The IC of claim 1, wherein the buffer layer comprises a first buffer film, a second buffer film, and a third buffer film, wherein the first buffer film is arranged between the substrate and the second buffer film, wherein the third buffer film is arranged between the second buffer film and the semiconductor layer, wherein a concentration of the first material in the first buffer film is greater than a concentration of the first material in the second buffer film and a concentration of the first material in the third buffer film is less than the concentration of the first material in the second buffer film.

4. The IC of claim 3, wherein a concentration of the second material in the first buffer film is less than a concentration of the second material in the second buffer film and a concentration of the second material in the third buffer film is greater than the concentration of the second material in the second buffer film, wherein a thickness of the first buffer film is less than a thickness of the second buffer film and a thickness of the third buffer film is greater than the thickness of the second buffer film.

5. The IC of claim 1, wherein a first concentration of the first material in the buffer layer discretely decreases at least three times in a first direction from the substrate towards the semiconductor layer, wherein a second concentration of the second material in the buffer layer discretely increases at least three times in the first direction.

6. The IC of claim 1, wherein a ratio of a thickness of the buffer layer to a thickness of the semiconductor layer is within a range of 0.01 to 0.10.

7. The IC of claim 1, wherein the substrate comprises opposing sidewalls defining a recess, wherein the semiconductor layer is arranged in the recess, wherein the IC further comprises:
an interlayer arranged in the recess between the buffer layer and the substrate, wherein the interlayer comprises the first material.

8. The IC of claim 7, further comprising:
a passivation layer over a top surface of the semiconductor layer and a top surface of the buffer layer, wherein the passivation layer contacts inner sidewalls of the interlayer and has a top surface aligned with a top surface of the substrate, wherein the passivation layer comprises the first material.

9. The IC of claim 7, further comprising:
a plurality of first contact regions disposed in the substrate and laterally offset from the interlayer, wherein the first contact regions are spaced on opposing sides of the semiconductor layer;
a second contact region disposed in the semiconductor layer; and
a plurality of outer lateral wells disposed in the substrate and underlying the plurality of first contact regions, wherein the outer lateral wells continuously laterally extend from under a corresponding first contact region, through the interlayer and the buffer layer, to the semiconductor layer, wherein a doping type of the first contact regions and the outer lateral wells is different from a doping type of the second contact region.

10. An integrated chip (IC), comprising:
a substrate comprising an upper surface;
a germanium layer over the upper surface of the substrate;
an isolation structure disposed in the substrate and on opposing sides of the germanium layer;
a buffer layer disposed between the upper surface of the substrate and the germanium layer, wherein the buffer layer comprises silicon and germanium; and
a passivation layer contacting a top surface of the germanium layer, wherein the passivation layer comprises epitaxial silicon.

11. The IC of claim 10, wherein a lattice constant of the buffer layer discretely increases at least two times from a bottom surface of the buffer layer in a direction towards a bottom surface of the germanium layer.

12. The IC of claim 10, wherein a concentration of germanium in the buffer layer continuously increases from a bottom surface of the buffer layer in a first direction towards a bottom surface of the germanium layer, wherein a concentration of silicon in the buffer layer continuously decreases from the bottom surface of the buffer layer in the first direction.

13. The IC of claim 10, wherein the substrate comprises a first doping type, wherein the IC further comprises:
a first avalanche well disposed in the substrate and under the germanium layer, wherein the first avalanche well comprises a second doping type opposite the first doping type;
a first contact region disposed in the substrate and laterally wrapped around the germanium layer, wherein the first contact region is offset from the buffer layer and comprises the second doping type;
a vertical connection well disposed in the substrate and continuously extending from the first contact region to the first avalanche well, wherein the vertical connection well comprises the second doping type; and
a second avalanche well disposed in the substrate and between the germanium layer and the second avalanche well, wherein the second avalanche well comprises the first doping type.

14. The IC of claim 10, wherein the substrate comprises opposing sidewalls extending from a top surface of the substrate to the upper surface and defining a recess, wherein the germanium layer and the buffer layer are disposed in the recess, wherein the IC further comprises:
an interlayer contacting the opposing sidewalls of the substrate, wherein the interlayer is disposed between the substrate and the buffer layer, wherein a thickness of the interlayer is greater than a thickness of the buffer layer and a thickness of the passivation layer is greater than is greater than the thickness of the buffer layer.

15. The IC of claim 10, wherein a bottommost surface of the germanium layer is vertically above a top surface of the substrate, and wherein outer sidewalls of the germanium layer are aligned with outer sidewalls of the buffer layer.

16. The IC of claim 15, wherein the passivation layer contacts the outer sidewalls of the germanium layer and the outer sidewalls of the buffer layer, and wherein a bottom surface of the passivation layer is aligned with a bottom surface of the buffer layer.

17. A method for forming an integrated chip (IC), the method comprising:
forming a buffer layer on a substrate, wherein the substrate comprises a first material, wherein the buffer layer comprises the first material and a second material different from the first material;
forming a semiconductor layer on the buffer layer, wherein the semiconductor layer comprises the second material; and
forming a passivation layer along a top surface of the semiconductor layer, wherein the passivation layer comprises the first material.

18. The method of claim 17, further comprising:
forming a first avalanche well in the substrate and below the semiconductor layer;
forming a vertical connection well in the substrate and on opposing sides of the first avalanche well;
forming a first contact region in the substrate and over the vertical connection well, wherein when viewed in top view the vertical connection well and the first contact region are ring-shaped;
forming a second avalanche well in the substrate and over the first avalanche well;
forming a second contact region in the semiconductor layer, wherein the second contact region and the second avalanche well comprise a first doping type; and
wherein the first avalanche well, the vertical connection well, and the first contact region comprise a second doping type opposite the first doping type.

19. The method of claim 17, wherein forming the buffer layer comprises:
epitaxially growing a first buffer film on the substrate;
epitaxially growing a second buffer film on the first buffer film; and
epitaxially growing a third buffer film on the second buffer film, wherein concentrations of the first and second materials in the first buffer film, the second buffer film, and the third buffer film are different from one another, and wherein thicknesses of the first buffer film, the second buffer film, and the third buffer film are respectively less than a thickness of the passivation layer.

20. The method of claim 17, further comprising:
performing a first etch into the substrate to form a recess;
forming an interlayer lining the recess, wherein the interlayer comprises the first material, wherein the interlayer is formed by a first epitaxial process and the buffer layer is formed by a second epitaxial process, wherein a thickness of the interlayer is greater than a thickness of the buffer layer; and
wherein the buffer layer is formed on the interlayer in the recess, wherein the semiconductor layer is formed in the recess.
